(19) United States
(12) Patent Application Publication
(10) Pub. No.: US 2013/0313722 A1
(43) Pub. Date: Nov. 28, 2013

(54) THROUGH-SILICON VIA (TSV) SEMICONDUCTOR DEVICES HAVING VIA PAD INLAYS

(71) Applicant: SAMSUNG ELECTRONICS CO., LTD., Suwon-si (KR)

(72) Inventors: Son-Kwan Hwang, Suwon-si (KR); Byung-Lyul Park, Seoul (KR); Hyun-Soo Chung, Hwasung-si (KR); Jin-Ho Chun, Seoul (KR); Gil-Heyun Choi, Seoul (KR)

(73) Assignee: Samsung Electronics Co., Ltd., Suwon-si (KR)

(21) Appl. No.: 13/763,294

(22) Filed: Feb. 8, 2013

(30) Foreign Application Priority Data
May 22, 2012 (KR) 10-2012-0054413

(51) Int. Cl. H01L 23/498

(52) U.S. Cl. CPC H01L 23/49827
USPC 257/774

(57) ABSTRACT

A semiconductor device includes an insulating layer on a surface of a substrate, a through-via structure vertically passing through the substrate and the insulating layer and being exposed on the insulating layer, and a via pad on a surface of the exposed through-via structure. The via pad includes a via pad body, and a via pad inlay below the via pad body and protruding into the insulating layer and surrounding the through-via structure. The via pad body and the via pad inlay include a via pad barrier layer directly on the insulating layer and a via pad metal layer on the via pad barrier layer.

### CROSS-REFERENCE TO RELATED APPLICATION

This application claims priority under 35 U.S.C. §119 to Korean Patent Application No. 10-2012-0054413 filed on May 22, 2012, the disclosure of which is hereby incorporated by reference in its entirety.

### BACKGROUND

Embodiments of the inventive concepts relate to semiconductor devices having via pads.

A Through-Silicon Via (TSV) is a vertical electrical connection (via) that passes through a silicon wafer or die. The term “TSV” is also generically used for vertical electrical connections that pass through a substrate (wafer or die) that is not made of silicon, but, instead may be composed of another semiconductor such as silicon carbide, or an insulator such as glass. TSV technology may be used to create three-dimensional packages and three-dimensional integrated circuits, which may improve the integration density and/or performance of microelectronic devices.

### SUMMARY

Embodiments of the inventive concepts can provide semiconductor devices having a through-via structure and a via pad, and methods of fabricating the same.

Other embodiments of the inventive concepts can provide semiconductor devices having a via pad and a redistribution structure, and methods of fabricating the same.

Still other embodiments of the inventive concepts can provide via pads having an inlay, semiconductor devices having the via pad, and methods of fabricating the same.

Still other embodiments of the inventive concepts can provide redistribution structures having an inlay, semiconductor devices having the redistribution structure, and methods of fabricating the same.

Still other embodiments of the inventive concepts can provide redistribution pads having an inlay and semiconductor devices having the redistribution pad, and methods of fabricating the same.

Still other embodiments of the inventive concepts can provide via pads which overlap a through-via structure and have an inlay, semiconductor devices having the via pad having the inlay, and methods of fabricating the same.

Still other embodiments of the inventive concepts can provide via pads, redistribution structures, and/or redistribution pads which are integrally formed, semiconductor devices having the same, and methods of fabricating the same.

Still other embodiments of the inventive concepts can provide memory modules, semiconductor modules, electronic systems, and mobile apparatus including at least one of components and semiconductor devices which resolve various problems.

The technical objectives of the inventive concepts are not limited to the above disclosure; other objectives may become apparent to those of ordinary skill in the art based on the following description.

In accordance with aspects of the inventive concepts, a semiconductor device includes a substrate, a through-via structure vertically passing through the substrate with an end surface of the through-via structure being exposed on a surface of the substrate, and a via pad on a surface of the through-via structure. The via pad includes a via pad body and a via pad inlay below the via pad body and located at a lateral sides of the through-via structure.

In accordance with other aspects of the inventive concepts, a semiconductor device includes a substrate, an insulating layer on a surface of the substrate, a through-via structure vertically passing through the substrate and the insulating layer with a surface of the through-via structure being exposed on the insulating layer, and a via pad on a surface of the exposed through-via structure. The via pad includes a via pad body, and a via pad inlay below the via pad body and protruding into the insulating layer to surround the through-via structure. The via pad body and the via pad inlay include a via pad barrier layer directly on the insulating layer and a via pad metal layer on the via pad barrier layer.

In accordance with still other aspects of the inventive concepts, a semiconductor device includes a substrate having first and second opposing substrate faces and a through-via structure that extends through the substrate, from the first substrate face to the second substrate face, and includes a through-via structure sidewall. A via pad is provided on the substrate face and electrically connected to the through-via structure. The via pad includes a first via pad face adjacent the first substrate face, a second via pad face remote from the first substrate face and a via pad sidewall between the first via pad face and the second via pad face. The first via pad face is non-planar between the via pad sidewall and the through-via sidewall. In some embodiments, the first via pad face includes at least one via pad inlay between the via pad sidewall and the through-via structure sidewall. Moreover, a sidewall of the at least one via pad inlay may directly contact the through-via structure sidewall. A non-planar barrier layer may also be provided between the non-planar first via pad face and the first substrate face. Finally, the second via pad face may be planar between the sidewall and the through-via sidewall.

### BRIEF DESCRIPTION OF THE DRAWINGS

The foregoing and other features and advantages of the inventive concepts will be apparent from the more particular description of embodiments of the inventive concepts, as illustrated in the accompanying drawings in which like reference characters refer to the same parts throughout the different views. The drawings are not necessarily to scale, emphasis instead being placed upon illustrating the principles of the inventive concepts. In the drawings:

FIGS. 1A and 1B are surface layout views schematically illustrating through-via structures, via pads, redistribution structures, and redistribution pads of semiconductor devices in accordance with various embodiments of the inventive concepts;

FIG. 2A is a top view or layout view schematically illustrating through-via structures and via pads of semiconductor devices in accordance with embodiments of the inventive concepts;

FIGS. 2B to 2E are cross-sectional views schematically illustrating through-via structures and via pads of semiconductor devices in accordance with various embodiments of the inventive concepts;

FIGS. 3A to 3C are top views or layout views schematically illustrating via pads in accordance with various embodiments of the inventive concepts;

FIGS. 4A and 4B are cross-sectional views schematically illustrating via pads in accordance with various embodiments of the inventive concepts;

FIGS. 5A and 5B are top views and cross-sectional views schematically illustrating redistribution structures in accordance with various embodiments of the inventive concepts;

FIG. 6A is a plan view schematically illustrating a semiconductor device in accordance with various embodiments of the inventive concepts, FIG. 6B shows cross-sectional views taken along lines I-I′, II-II′, and III-III′ in FIG. 6A, and FIG. 6C is a cross-sectional view taken along line IV-IV′ in FIG. 6A;

FIG. 7A is a plan view schematically illustrating a semiconductor device in accordance with various embodiments of the inventive concepts, FIG. 7B shows cross-sectional views taken along lines V-V′, VI-VI′, and VII-VII′ in FIG. 7A, and FIG. 7C is a cross-sectional view taken along line VIII-VIII′ in FIG. 7A;

FIG. 8A is a plan view schematically illustrating a semiconductor device in accordance with various embodiments of the inventive concepts, FIG. 8B shows cross-sectional views taken along lines IX-IX′, X-X′, and XI-XI′ in FIG. 8A, and FIG. 8C is a cross-sectional view taken along line XII-XII′ in FIG. 8A;

FIGS. 9A to 9D are flowcharts describing fabrication methods of semiconductor devices in accordance with various embodiments of the inventive concepts;

FIGS. 10A to 10N are cross-sectional views schematically describing a fabrication method of a semiconductor device in accordance with various embodiments of the inventive concepts;

FIGS. 11A to 11F are cross-sectional views schematically describing a fabrication method of a semiconductor device in accordance with various embodiments of the inventive concepts;

FIGS. 12A and 12B, to FIGS. 17A and 17B are cross-sectional views schematically describing a fabrication method of a semiconductor device in accordance with various embodiments of the inventive concepts;

FIG. 18 is a schematic view illustrating a memory module including at least one of semiconductor devices in accordance with various embodiments of the inventive concepts.

FIG. 19 is a schematic view illustrating a semiconductor module including at least one of semiconductor devices in accordance with various embodiments of the inventive concepts;

FIGS. 20 and 21 are block diagrams schematically illustrating electronic systems including at least one of semiconductor devices in accordance with various embodiments of the inventive concepts; and

FIG. 22 is a schematic diagram schematically illustrating a mobile apparatus including at least one of semiconductor devices in accordance with various embodiments of the inventive concepts.

### DETAILED DESCRIPTION OF THE EMBODIMENTS

Various embodiments will now be described more fully with reference to the accompanying drawings in which some embodiments are shown. These inventive concepts may, however, be embodied in different forms and should not be construed as limited to the embodiments set forth herein. Rather, these embodiments are provided so that this disclosure is thorough and complete and fully conveys the inventive concepts to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concepts.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concepts.

Unless otherwise defined, all terms (including technical and scientific terms) used herein have the same meaning as commonly understood by one of ordinary skill in the art to which this inventive concepts belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

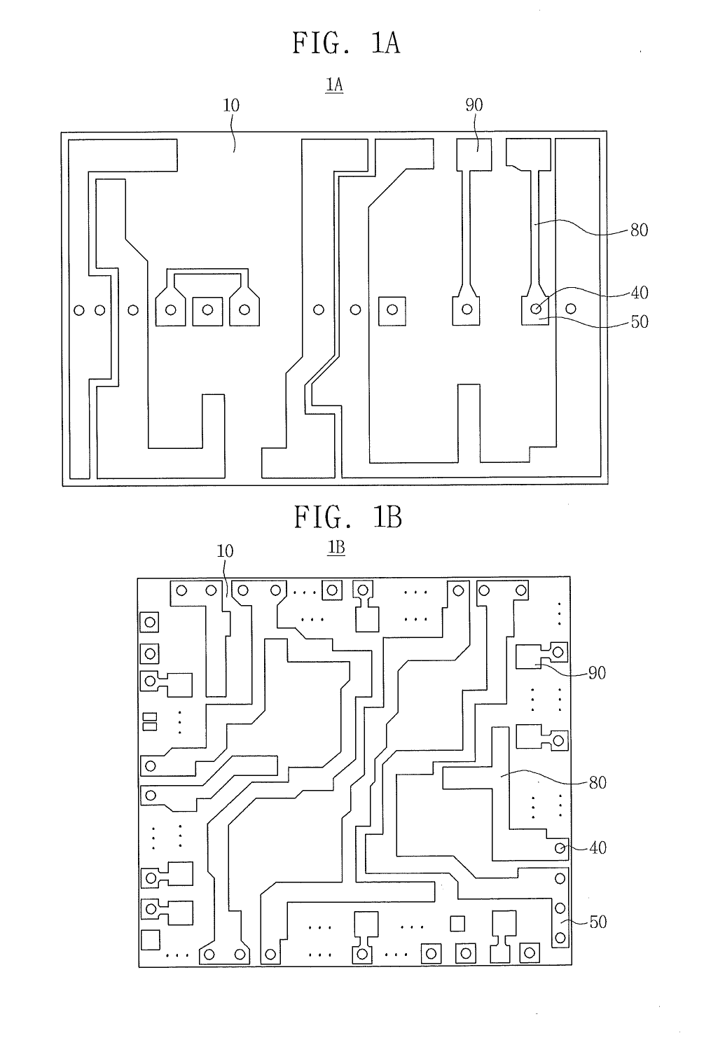

FIGS. 1A and 1B are surface layout views schematically illustrating through-via structures 40, via pads 50, redistribution structures 80, and redistribution pads 90 of semiconductor devices 1A and 1B in accordance with various embodiments of the inventive concepts.

Referring to FIGS. 1A and 1B, semiconductor devices 1A and 1B in accordance with various embodiments of the inventive concepts may include through-via structures 40, via pads 50, redistribution structures 80, and redistribution pads 90, which are exposed on a surface of a substrate 10.

The surface of the substrate 10 may include a single element and/or compound semiconductor material, such as silicon or silicon carbide, and one or more layers, such as silicon nitride, silicon oxide, polyimide, a photosensitive polyimide, benzocyclobutene (BCB), or other organic or inorganic polymers. Non-semiconductor substrates that include glass or metal may also be used.

The through-via structures 40 may partially or completely pass through the substrate 10. One ends of the through-via structures 40 may be exposed on the surface of the substrate 10.

The via pads 50 may be variously arranged on the surface of the substrate 10 to overlap the through-via structures 40. The via pads 50 may be electrically connected w the through-via structures 40.

The redistribution structures 80 may be electrically and/or physically connected to the via pads 50. The redistribution structures 80 may electrically and/or physically connect the via pads 50 to the redistribution pads 90. The redistribution pads 90 may be electrically and/or physically connected to the redistribution structures 80. The redistribution pads 90 may be parts of the redistribution structures 80.

Referring again to FIG. 1A, the through-via structures 40 may be arranged in rows or columns along a virtual straight line passing through the center of the substrate 10. In FIG. 1A, although the through-via structures 40 are illustrated as being arranged in a row, the through-via structures 40 may be arranged in a plurality of rows or columns. The redistribution pads 90 may be arranged in various locations of the substrate 10, for example, in an outer region of the substrate 10.

Referring again to FIG. 1B, the through-via structures 40 may be arranged in a row in an outer region of the substrate 10. The redistribution pads 90 may be arranged in various locations of the substrate 10. The semiconductor devices 1A and 1B in accordance with the various embodiments of the inventive concepts may distribute supply voltage, reference voltage, ground voltage, and/or other various signals which are received through the through-via structures 40, to the redistribution pads 90 which are arranged in various locations, using the via pads 50 and the redistribution structures 80. In addition, the semiconductor devices 1A and 1B may distribute supply voltage, reference voltage, ground voltage, and other various signals which are received through the redistribution pads 90, to the via pads 50 and/or the through-via structures 40 which are arranged in various locations, using the redistribution structures 80.

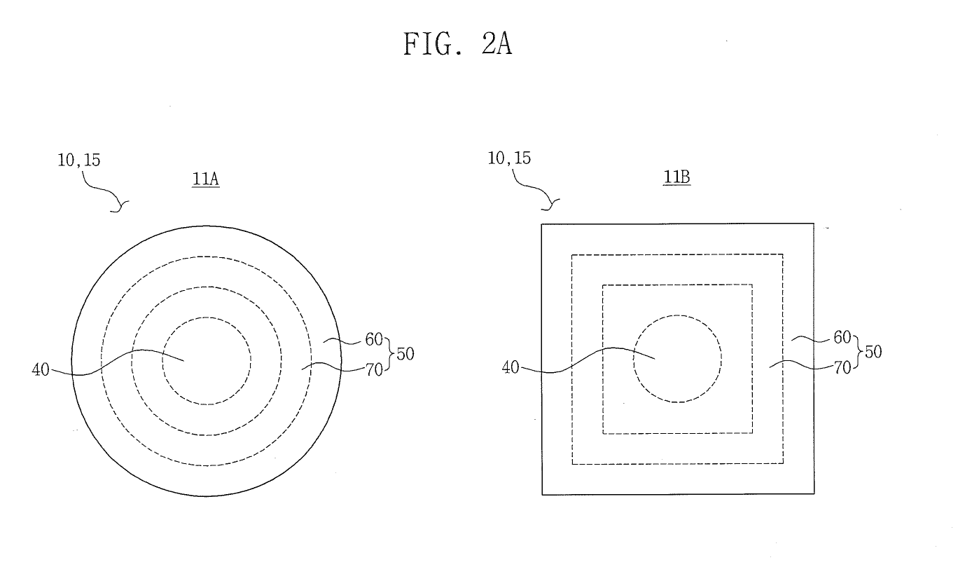

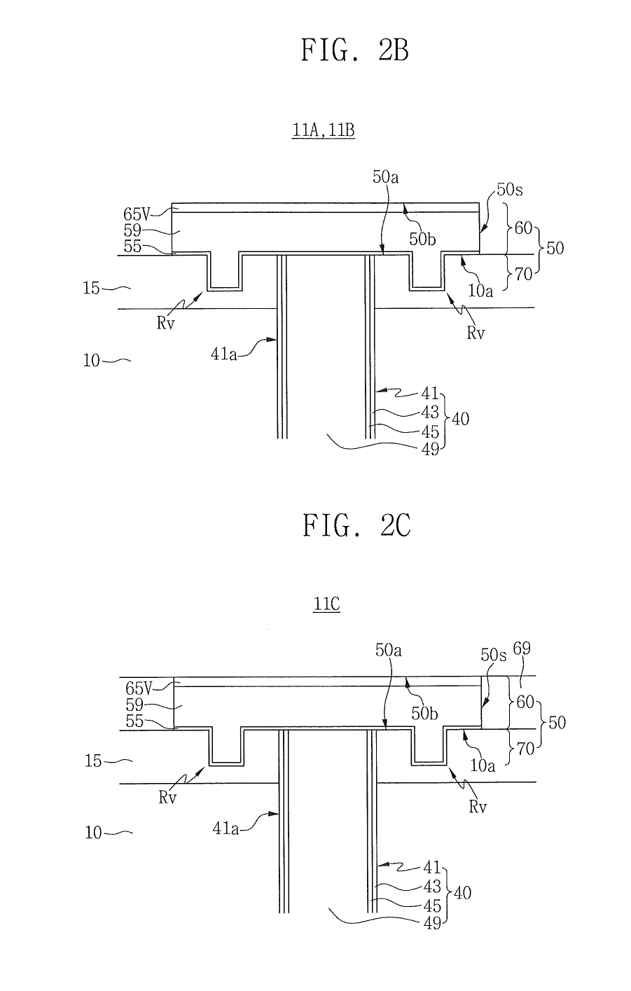

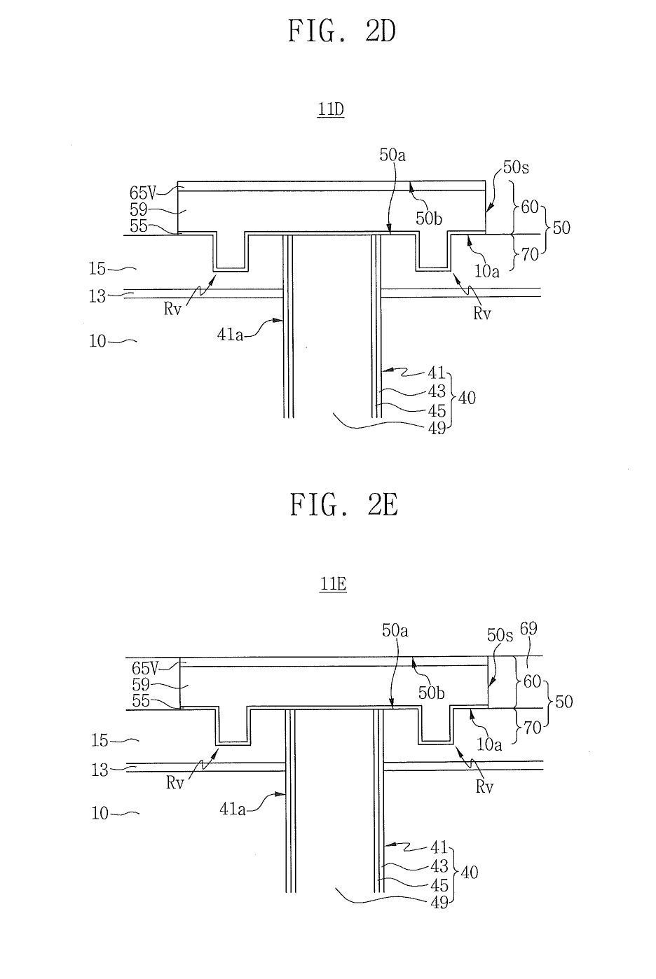

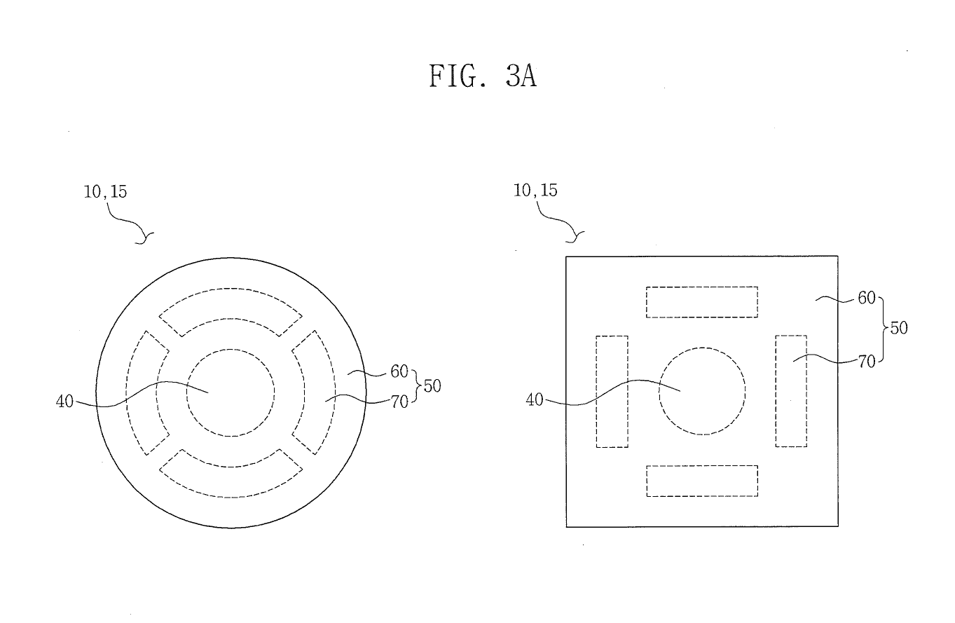

FIG. 2A is a top view or layout view schematically illustrating through-via structures 40 and via pads 50 of semiconductor devices 11A to 11E in accordance with embodiments of the inventive concepts, and FIGS. 2B to 2E are cross-sectional views schematically illustrating through-via structures 40 and via pads 50 of semiconductor devices 11A to 11E in accordance with various embodiments of the inventive concepts.

Referring to FIGS. 2A and 2B, the semiconductor devices 11A and 11B in accordance with various embodiments of the inventive concepts may include through-via structures 40 passing through a substrate 10 and a surface insulating layer 15, and via pads 50 formed on the through-via structures 40.

The substrate 10 may include bulk silicon or silicon-on-insulator (SOI) and/or any of the other materials described above.

The surface insulating layer 15 may be formed on the substrate 10. For example, the surface insulating layer 15 may include silicon nitride, silicon oxide, or polyimide. The substrate includes first and second opposing substrate faces.

The through-via structure 40 may perpendicularly pass through the substrate 10 and the surface insulating layer 15 from the first substrate face to the second substrate face. A top surface of the through-via structure 40 may be exposed on the surface insulating layer 15. The surface of the through-via structure 40 may be the same as a surface of the surface insulating layer 15.

The through-via structure 40 may include a via liner 43 conformally formed on an inner wall of a via hole 41, a via barrier layer 45 conformally formed on an inner wall of the via liner 43, and a via plug 49 formed in the via barrier layer to fill the inside of the via hole 41. The via hole 41 may pass through a part or all of the substrate 10, and the entire surface insulating layer 15. The via liner 43 may include an insulating material such as silicon oxide or silicon nitride. The via barrier layer 45 may include a barrier metal. For example, the via barrier layer 45 may be formed of a single or multi layer including Ti, TiN, Ta, TaN, TiW, WN, other refractory metals, or metal composites. The via plug 49 may include Cu, W, Al, or another metal. The through-via structure includes a through-via sidewall 41a.

The via pads 50 may be formed substantially in a shape of a circular or polygonal mesa. The via pads 50 may include a first via pad face 50a adjacent the first substrate face 10a, a second via pad face 50b remote from the first substrate face 10a, and a via pad sidewall 50s between the first via pad face 50a and the second via pad face 50b. As shown, for example, in FIG. 2B, the first via pad face 50a is non-planar between the via pad sidewall 50s and the through-via sidewall 41a. The via pads 50 may include via pad bodies 60 and the non-planar first via pad face 50a may include via pad inlays 70 formed at lower portions of the via pads 50. The via pad inlays 70 may include sidewalls and bottoms. The via pad bodies 60 may be formed on an outside or upper portion of the surface insulating layer 15. The via pad inlays 70 may be located at sides of the through-via structure 40.

The via pad inlays 70 may be spaced apart from the through-via structure 40 in a horizontal direction. For example, the via pad inlays 70 may be spaced apart from a sidewall 41a of the through-via structure 40. The via pad inlays 70 may have concentric ring or polygonal shapes to surround the through-via structure 40 in a top view. A diameter or a lateral width of the via pad inlays 70 may be smaller than a diameter or a lateral width of the via pad bodies 60. For example, the via pad inlays 70 may be overlapped and blinded by the via pad bodies 60 in a top view. The via pad inlays 70 may protrude downward in a side view or a cross-sectional view. The via pad inlays 70 may be formed in an inlaid shape inside the surface insulating layer 15 For example, a surface of the surface insulating layer 15 may be recessed to form via pad recesses Rv, and the via pad inlays 60 may have a downward protruding shape to fill the via pad recesses Rv.

The via pad inlays 70 may be integrally formed with the via pad bodies 60. For example, the via pad bodies 60 and the via pad inlays 70 may include the same material. The via pad bodies 60 and the via pad inlays 70 may be materially continuous to each other.

The via pad 50 may include a via pad barrier layer 55, a via pad metal layer 59, and a via pad capping layer 65V. The via pad barrier layer 55 may be conformally formed along a surface profile of the surface insulating layer 15. For example, the via pad barrier layer 55 may be conformally formed on a surface of the surface insulating layer 15 and a surface of the via pad recess Rv. The via pad barrier layer 55 may be formed of a single or multi layer including Ti, TiN, Ta, TaN, TiW, WN, another refractory metal and/or a metal composite.

The via pad metal layer 59 may be directly formed on the via pad barrier layer 55. The via pad metal layer 59 may include Cu, W, Al, Ni, Sn, Ag, Au and/or another metal.

The via pad capping layer 65V may be formed on the via pad metal layer 59 to cover a surface of the via pad metal layer 59. The via pad capping layer 65V may be formed of a single or multi layer including Ni, Ag and/or a composite thereof. The via pad barrier layer 55 may extend to be materially continuous below the via pad bodies 60 and the via pad inlays 70.

The via pad metal layer 59 may be formed as a main body of the via pad bodies 60 and the via pad inlays 70. For example, the via pad bodies 60 and the via pad inlays 70 may share the via pad barrier layer 55 and the via pad metal layer 59. Or, the via pad barrier layer 55 and the via pad metal layer 59, depending on the location, may be included as components in the via pad bodies 60 and the via pad inlays 70.

Referring to FIGS. 2A and 2C, a semiconductor device 11C in accordance with embodiments of the inventive concepts may include through-via structures 40 passing through the substrate 10 and surface insulating layer 15, and via pads 50 formed on the through-via structures 40, and further include a passivation layer 69 covering the surface insulating layer 15 and sidewalls of the via pad 50. The passivation layer 69 may include silicon nitride, silicon oxide, polyimide, a photosensitive polyimide, a BCB and/or other organic or inorganic polymers.

Referring to FIGS. 2A and 2D, a semiconductor device 11D in accordance with embodiments of the inventive concepts may include through-via structures 40 passing through the substrate 10 and surface insulating layer 15, and via pads 50 formed on the through-via structures 40, and further include a buffer insulating layer 13 between a surface of the substrate 10 and the surface insulating layer 15. The buffer insulating layer 13 may include silicon oxide or silicon nitride. For example, the buffer insulating layer 13 may include silicon oxide, and the surface insulating layer 15 may include silicon nitride.

Referring to FIG. 2E, a semiconductor device 11E in accordance with embodiments of the inventive concepts may include through-via structures 40 passing through the substrate 10 and surface insulating layer 15, and via pads 50 formed on the through-via structures 40, and further include a buffer insulating layer 13 between a surface of the substrate 10 and the surface insulating layer 15, and a passivation layer 69 covering the surface insulating layer 15 and sidewalls of the via pad 50.

The semiconductor devices 11A-11E in accordance with the various embodiments of the inventive concepts may include the via pad barrier layer 55 which becomes longer and wider by including the via pad inlays 70. For example, a length of the via pad barrier layer 55 from the through-via structures 40 to an edge of the via pad 50 may become longer corresponding to lengths of sidewalls of the via pad inlays 70. Accordingly, partial damage of the via pad barrier layer 55 generated during the process of selectively removing the via pad barrier layer 55 may be reduced and may become negligible. That is, even when undercutting occurs due to excessive removal of the via pad barrier layer 55 (to be explained in the following figure), damage of the via pad metal layer 59 may be prevented or mitigated. For example, when the via pad barrier layer 55 becomes damaged, a space between a surface of the surface insulating layer 15 and the via pad metal layer 59, e.g., an undercut, is generated, and then the via pad metal layer 59 may collapse and become tilted and partially damaged since the via pad metal layer 59 cannot be supported enough. However, since the semiconductor devices 11A-11E in accordance with the various embodiments of the inventive concepts have the via pad barrier layer 55 having sufficient length and area, adhesion between the surface insulating layer 15 or a lower material layer and the via pad metal layer 59 may be maintained sufficiently. In addition, the via pad body 60 may be maintained intact regardless of the damage of the via pad barrier layer 55, thanks to the via pad metal layer 59 forming the via pad inlays 70. For example, the via pad inlays 70 may add a mechanical and physical strength to the via pad body 60. In addition, since the area of the via pad barrier layer 55 increases, the adhesion of the via pad barrier layer 55 may become excellent. Further, even if a material configured to form the via pad barrier layer 55 is replaced with a less expensive material, the overall adhesion may be maintained similarly. That is, even without using a high-priced material with high etching resistance and high adhesive strength, the overall requirements of the via pad barrier layer 55 may be sufficiently met.

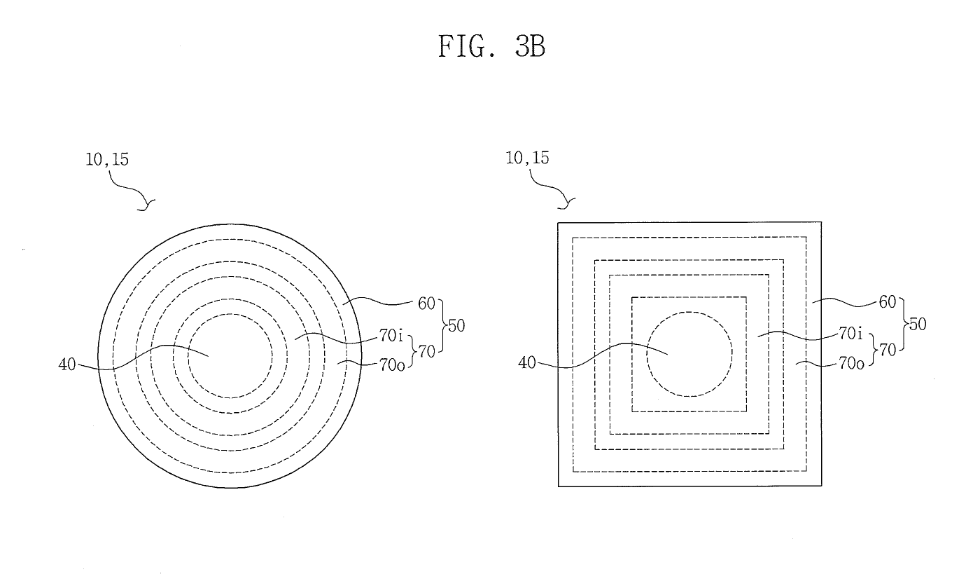

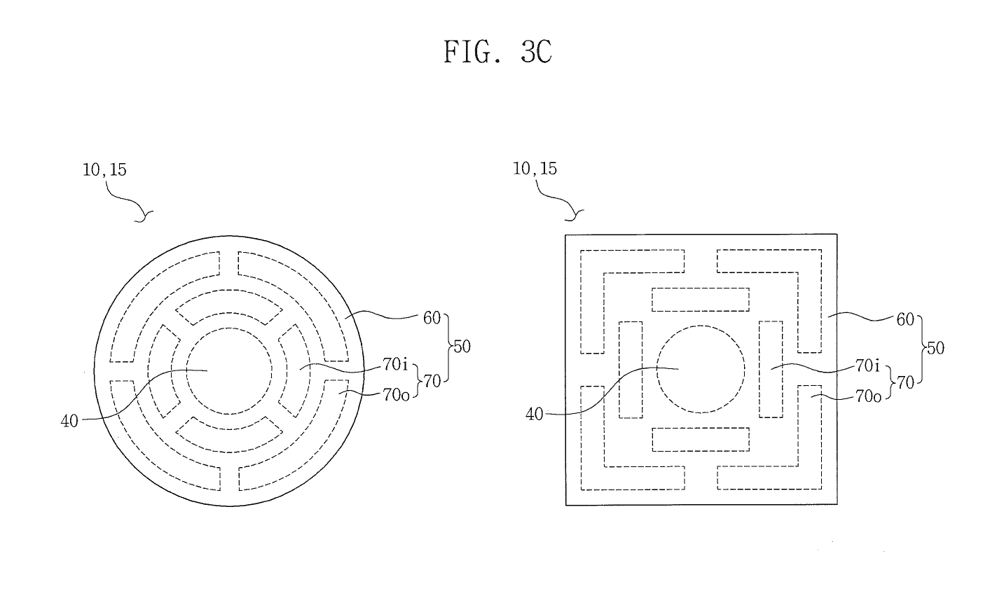

FIGS. 3A to 3C are top views or layout views schematically illustrating via pads 50 in accordance with various embodiments of the inventive concepts.

Referring to FIG. 3A, the via pads 50 in accordance with various embodiments of the inventive concepts may include via pad bodies 60 and bar-shaped via pad inlays 70. The bar-shaped via pad inlays 70 may be formed and arranged in shapes of a plurality of lines, boxes, or circular arcs.

Referring to FIG. 3B, the via pads 50 in accordance with embodiments of the inventive concepts may include via pad bodies 60, inner via pad inlays 70i, and outer via pad inlays 70o. The via pad inlays 70i and 70o may be formed in shapes of rings surrounding the through-via structures 40. In FIG. 3B, the via pad inlays 70i and 70o are illustrated in shapes of two concentric circles or concentric polygons.

Referring to FIG. 3C, the via pads 50 in accordance with embodiments of the inventive concepts may include bar-shaped inner and outer via pad inlays 70i and 70o. The inner via pad inlays 70i and the outer via pad inlays 70o may be formed to be arranged in a staggered relation, so as not to overlap or to reduce the degree of overlap. For example, the inner via pad inlays 70i may be formed in a bar shape, and the outer via pad inlays 70o may be formed in an elbow shape.

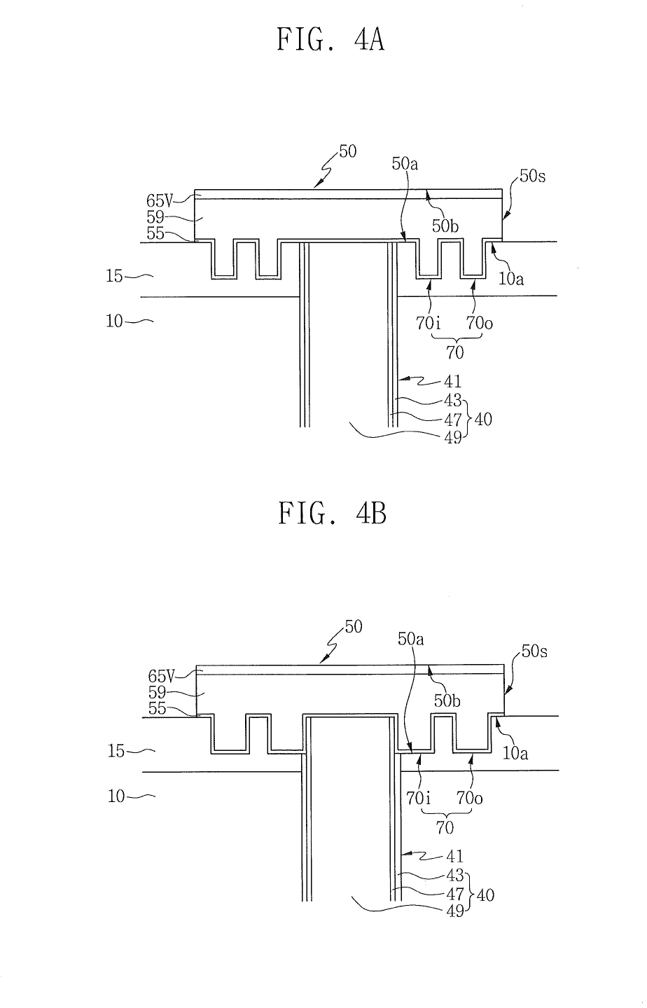

FIGS. 4A and 4B are cross-sectional views schematically illustrating via pads 50 in accordance with embodiments of the inventive concepts.

Referring to FIG. 4A, a via pad 50 in accordance with an embodiment of the inventive concepts may include multiple via pad inlays 70i and 70o. For example, referring again to FIGS. 3B and 3C, the via pad 50 may include inner via pad inlays 70i and outer via pad inlays 70o. The via pad inlays 70i and 70o may be spaced apart from a through-via structure 40.

Referring to FIG. 4B, a via pad 50 in accordance with an embodiment of the inventive concepts may include multiple via pad inlays 70i and 70o, wherein the inner via pad inlay 70i may be in contact with a through-via structure 40. For example, a side of a through-via structure 40 may be exposed on a surface insulating layer 15 and in direct contact with a via barrier layer 47. A sidewall of the inner via pad inlay 70i may contact the side of the through-via structure 40 to be electrically connected thereto.

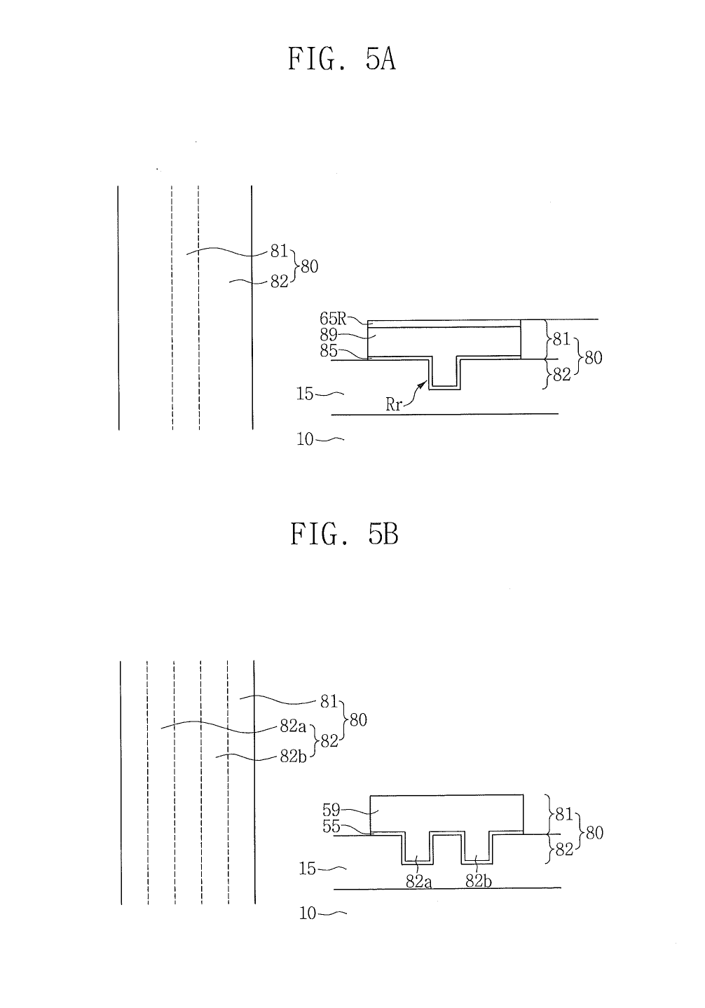

FIGS. 5A and 5B are top views and cross-sectional views schematically illustrating redistribution structures 80 in accordance with embodiments of the inventive concepts:

Referring to FIG. 5A, the redistribution structure 80 in accordance with embodiments of the inventive concepts may include an interconnection body 81 and an interconnection inlay 82. The interconnection inlay 82 may be extended along the interconnection body 81. The width of the interconnection inlay 82 may be smaller than the width of the interconnection body 81. For example, the interconnection inlay 82 may be overlapped by the interconnection body 81 so as to be fully covered by the interconnection body 81 in a top view. The interconnection inlay 82 may have a downward protruding shape in a side view or a cross-sectional view. The interconnection inlay 82 may be formed in a shape inlaid into the surface insulating layer 15. For example, the interconnection inlay 82 may have a downward protruding shape to fill an interconnection recess Rr which is formed by recessing a surface of the surface insulating layer 15. The interconnection body 81 may be formed integrally with the interconnection inlay 82. The interconnection body 81 and the interconnection inlay 82 may include the same material. The interconnection body 81 and the interconnection inlay 82 may be materially continuous.

The redistribution structures 80 may include an interconnection barrier layer 85, an interconnection metal layer 89, and/or an interconnection capping layer 65R. The interconnection barrier layer 85 may be conformally formed along a surface profile of the surface insulating layer 15. For example, the interconnection barrier layer 85 may be conformally formed on a surface of the surface insulating layer 15 and a surface of the interconnection recess Rc. The interconnection barrier layer 85 may be formed of a single or multi layer including Ti, TiN, Ta, TaN, TiW, WN and/or another refractory metal or a metal composite. The interconnection metal layer 89 may be formed on the interconnection barrier layer 85. The interconnection metal layer 89 may include Cu, W, Al, Ni, Sn, Ag, Au and/or another metal. The interconnection capping layer 65R may be formed on the interconnection metal layer 89 to cover a surface of the interconnection metal layer 89. The interconnection capping layer 65R may be formed of a single or multi layer including Ni, Ag and/or a composite including thereof. Accordingly, each of the interconnection body 81 and the interconnection inlay 82 may include the interconnection barrier layer 85, the interconnection metal layer 89, and the interconnection capping layer 65R.

Referring to FIG. 5B, the redistribution structure 80 in accordance with various embodiments of the inventive concepts may include an interconnection body 81 and a plurality of interconnection inlays 82a and 82b in parallel along the interconnection body 81. The interconnection inlays 82a and 82b may be spaced apart from each other. The interconnection inlays 82a and 82b may have narrower widths than the interconnection body 81, so as to be covered by the interconnection body 81 in a top view. The interconnection inlays 82a and 82b may protrude downward. Effects of the redistribution structure 80 having the interconnection inlays 80 may be understood, referring to the effects of the via pad 50 described with reference to FIGS. 2A to 2E.

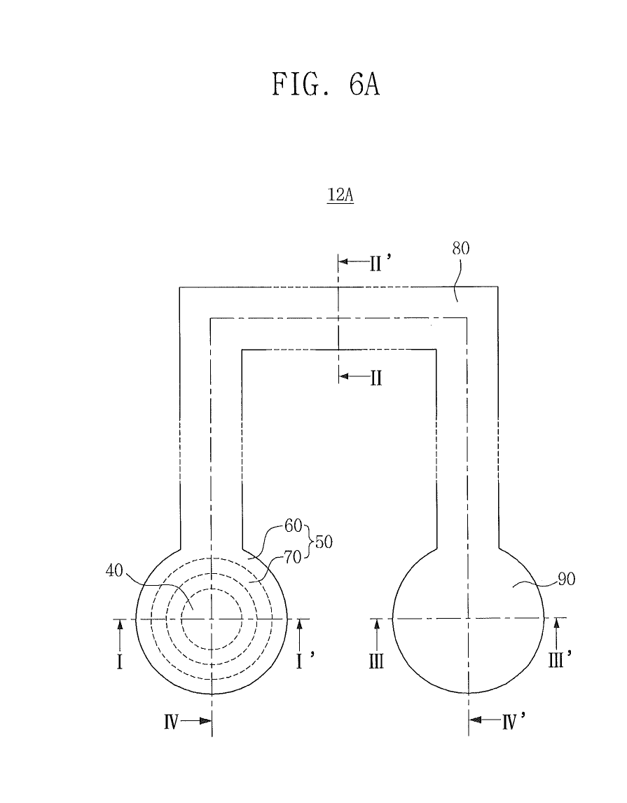

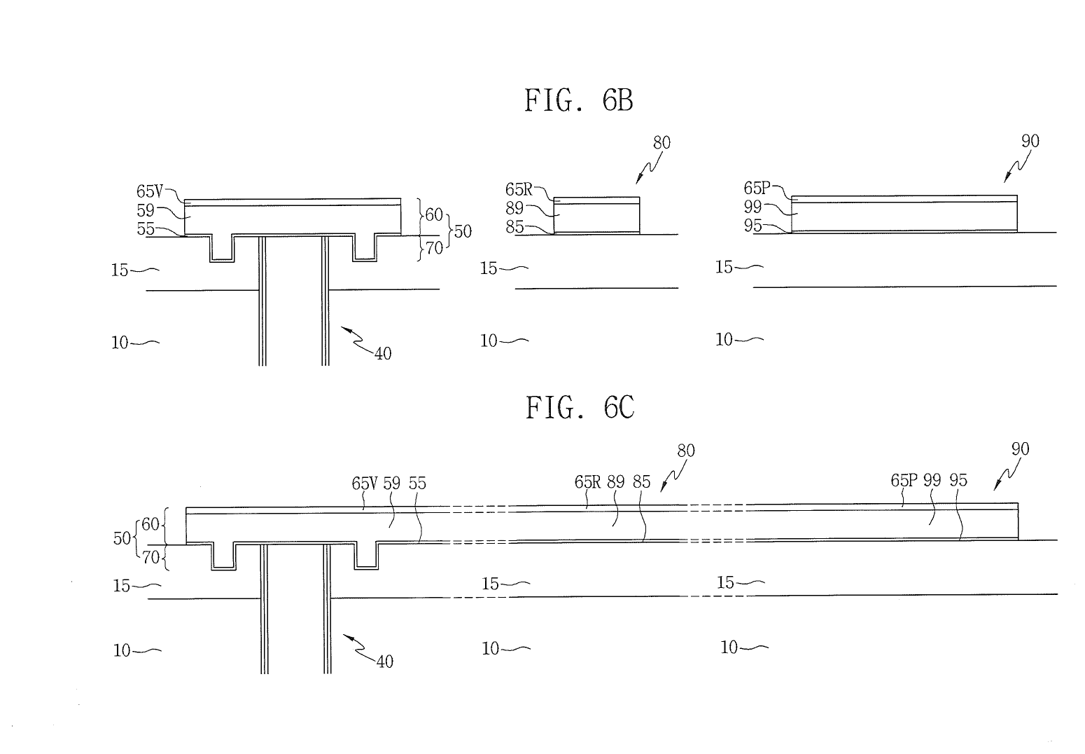

FIG. 6A is a plan view schematically illustrating a semiconductor device 12A in accordance with embodiments of the inventive concepts, FIG. 6B shows cross-sectional views taken along lines I-I′, II-I′, and III-III′ in FIG. 6A, and FIG. 6C is a cross-sectional view taken along line IV-IV′ in FIG. 6A.

Referring to FIGS. 6A to 6C, the semiconductor device 12A in accordance with the embodiments of the inventive concepts may include a through-via structure 40, a via pad 50, a redistribution structure 80, and a redistribution pad 90.

The through-via structure 40 may perpendicularly pass through a substrate 10 and a surface insulating layer 15 formed on the substrate 10, and a top surface of the through-via structure 40 may be exposed on the surface insulating layer 15. The via pad 50 may be arranged to be in direct contact with the top surface of the through-via structure 40 on the surface insulating layer 15. The via pad 50 may include a via pad body 60 and a via pad inlay 70. The through-via structures 40 and the via pad 50 may be understood in detail with reference to the other drawings herein.

The redistribution structure 80 may be directly arranged on the surface insulating layer 15. The redistribution structure 80 may be electrically connected to the via pad 50. For example, the redistribution structure 80 may be in direct contact with the via pad 50.

A via pad barrier layer 55 may be integrally formed with an interconnection barrier layer 85. For example, the via pad barrier layer 55 and the interconnection barrier layer 85 may have the same material so as to be materially continuous to each other.

A via pad metal layer 59 may be integrally formed with an interconnection metal layer 89. The via pad metal layer 59 and the interconnection metal layer 89 may have the same material so as to be materially continuous to each other.

A via pad capping layer 65V may be integrally formed with an interconnection capping layer 65R. For example, the via pad capping layer 65V and the interconnection capping layer 65R may have the same material so as to be materially continuous to each other.

The redistribution pad 90 may include a redistribution pad barrier layer 95, a redistribution pad metal layer 99, and a redistribution pad capping layer 65P. The redistribution pad 90 may be directly arranged on the surface insulating layer 15. The redistribution pad 90 may be electrically connected to the redistribution structure 80. For example, the redistribution pad 90 may directly contact the redistribution structure 80. The interconnection barrier layer 85 and the redistribution pad barrier layer 95 may include the same material to be materially continuous to each other. The interconnection capping layer 65R and the redistribution pad capping layer 65P may include the same material to be materially continuous to each other.

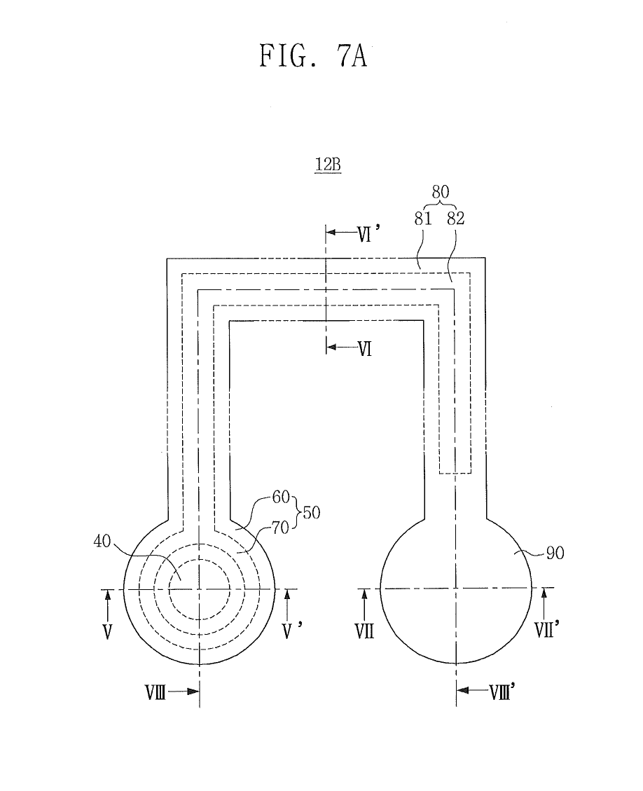

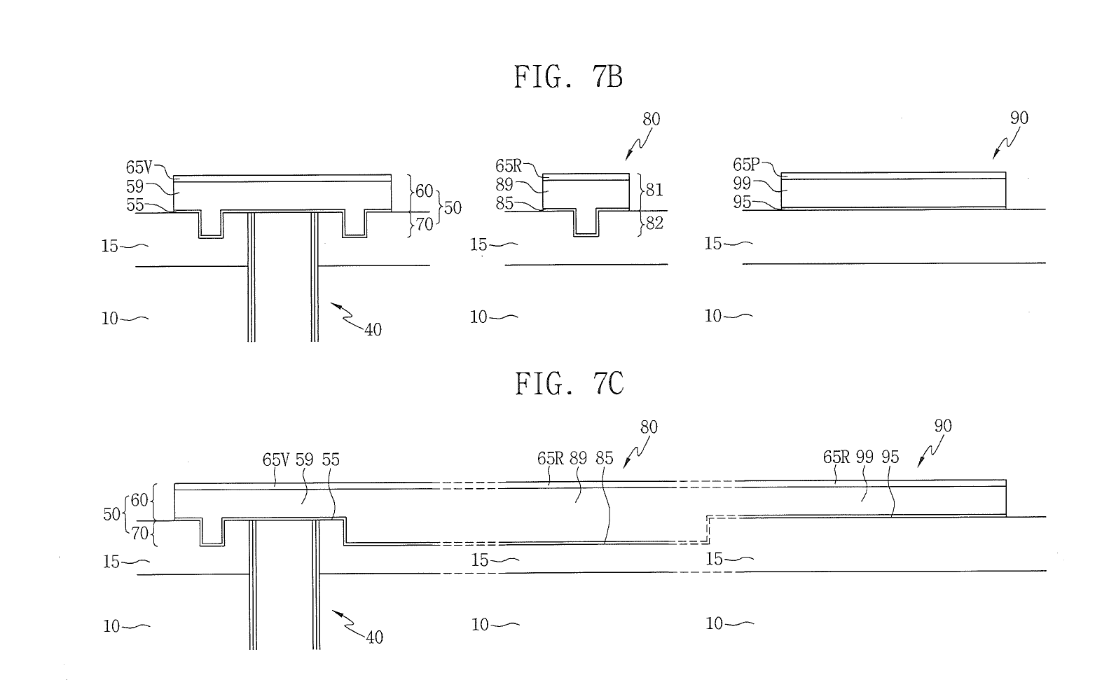

FIG. 7A is a plan view schematically illustrating a semiconductor device 12B in accordance with embodiments of the inventive concepts, FIG. 7B shows cross-sectional views taken along lines V-V′, VI-VI′, and VII-VII′ in FIG. 7A, and FIG. 7C is a cross-sectional view taken along line VIII-VIII′ in FIG. 7A.

Referring to FIGS. 7A to 7C, the semiconductor device 12B in accordance with the embodiments of the inventive concepts may include a through-via structure 40, a via pad 50, a redistribution structure 80, and a redistribution pad 90. The via pad 50 may include a via pad inlay 70, and the redistribution structure 80 may include an interconnection inlay 82. The via pad inlay 70 may be electrically connected to the interconnection inlay 82. For example, the via pad barrier layer 55 and the interconnection barrier layer 85 may have the same material to be materially continuous to each other. The via pad metal layer 59 and the interconnection metal layer 89 may have the same material to be materially continuous to each other. The via pad capping layer 65V and the interconnection capping layer 65R may have the same material to be materially continuous to each other. The via pad inlay 70 and the interconnection inlay 82 may have the same depth or the same thickness. For example, the via pad barrier layer 55 and the interconnection barrier layer 85 may have the same bottom surface and the same top surface. The via pad metal layer 59 and the interconnection metal layer 89 may have the same bottom surface and the same top surface. The via pad capping layer 65V and the interconnection capping layer 65R may have the same bottom surface and the same top surface.

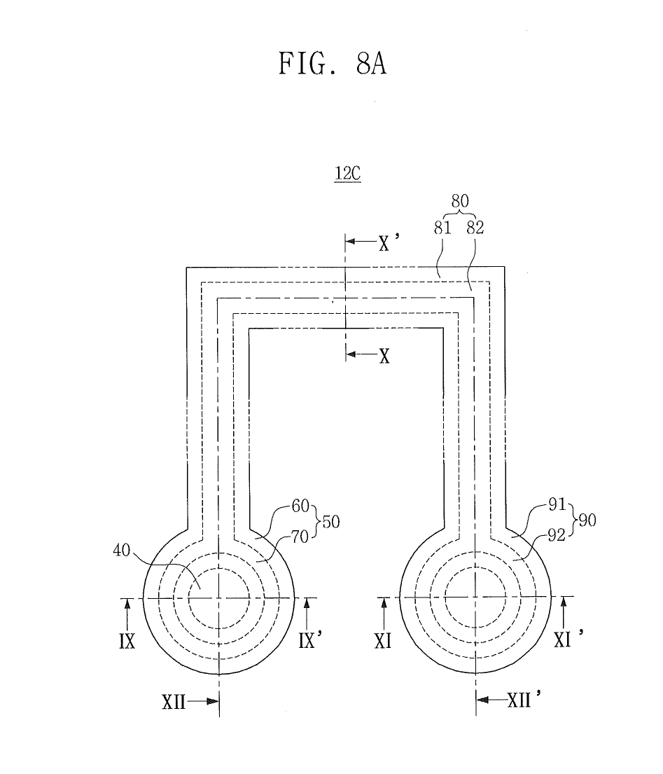

FIG. 8A is a plan view schematically illustrating a semiconductor device 12C in accordance with embodiments of the inventive concepts, FIG. 8B shows cross-sectional views taken along lines IX-IX′, X-X′, and XI-XI′ in FIG. 8A, and FIG. 8C is a cross-sectional view taken along line XII-XII′ in FIG. 8A.

Referring to FIGS. 8A to 8C, the semiconductor device 12C in accordance with the embodiments of the inventive concepts may include a through-via structure 40, a via pad 50, a redistribution structure 80, and a redistribution pad 90. The via pad 50 may include a via pad inlay 70, the redistribution structures 80 may include an interconnection inlay 82, and the redistribution pad 90 may include a redistribution pad inlay 92.

The interconnection inlay 82 may be electrically connected to the redistribution pad inlay 92. For example, the interconnection barrier layer 85 and the redistribution pad barrier layer 95 may have the same material to be materially continuous to each other. The interconnection metal layer 89 and the redistribution pad metal layer 99 may have the same material to be materially continuous to each other. The interconnection capping layer 65R and the redistribution pad capping layer 65P may have the same material to be materially continuous to each other. The interconnection inlay 82 and the redistribution pad inlay 92 may have the same depth or the same thickness. For example, the interconnection barrier layer 85 and the redistribution pad barrier layer 95 may have the same bottom surface and the same top surface. The interconnection metal layer 89 and the redistribution pad metal layer 99 may have the same bottom surface and the same top surface. The interconnection capping layer 65R and the redistribution pad capping layer 65P may have the same bottom surface and the same top surface.

The effects of the redistribution pad 90 having the redistribution pad inlay 92 may be understood referring to the effects of the via pad 50 described with reference to FIGS. 2A to 2E.

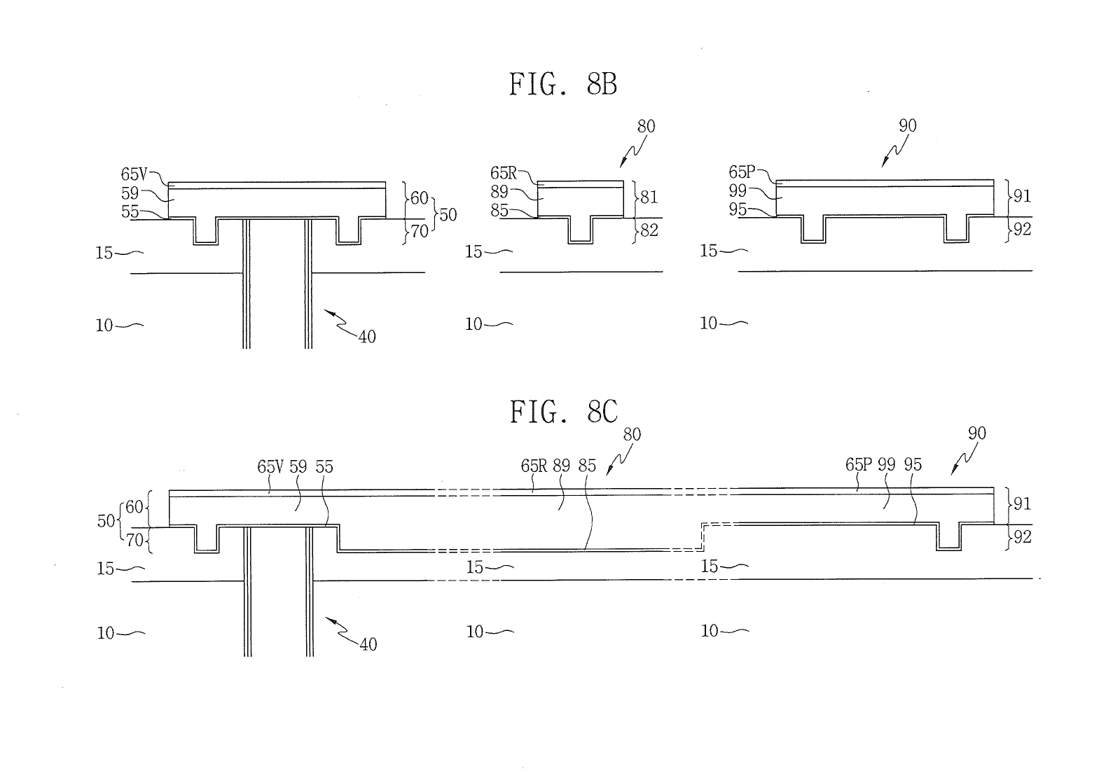

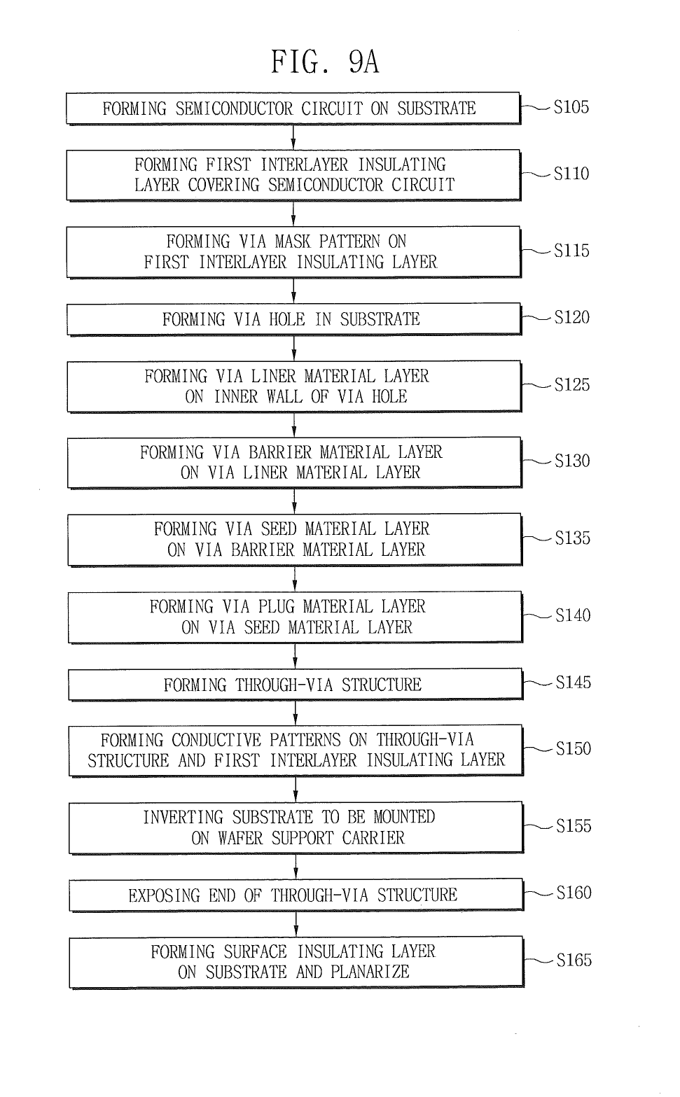

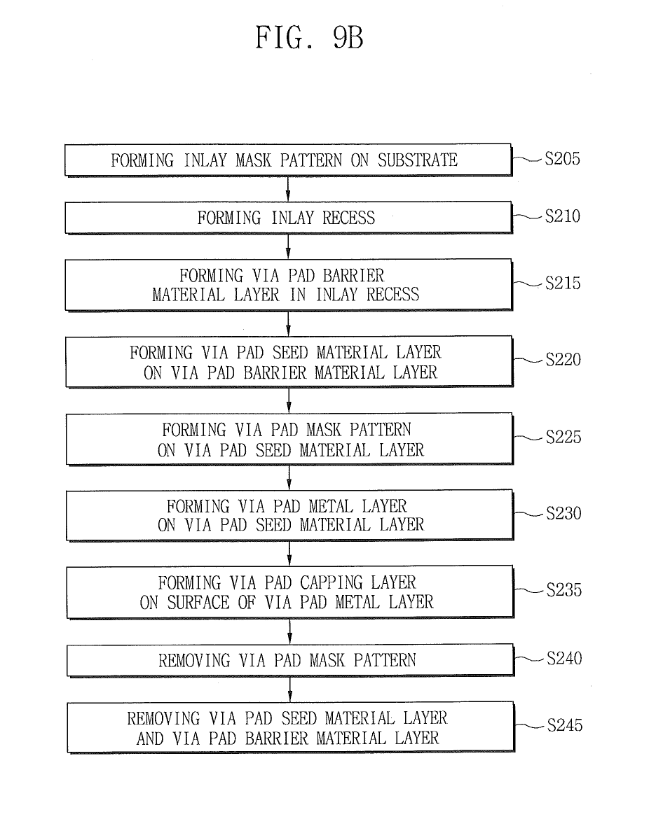

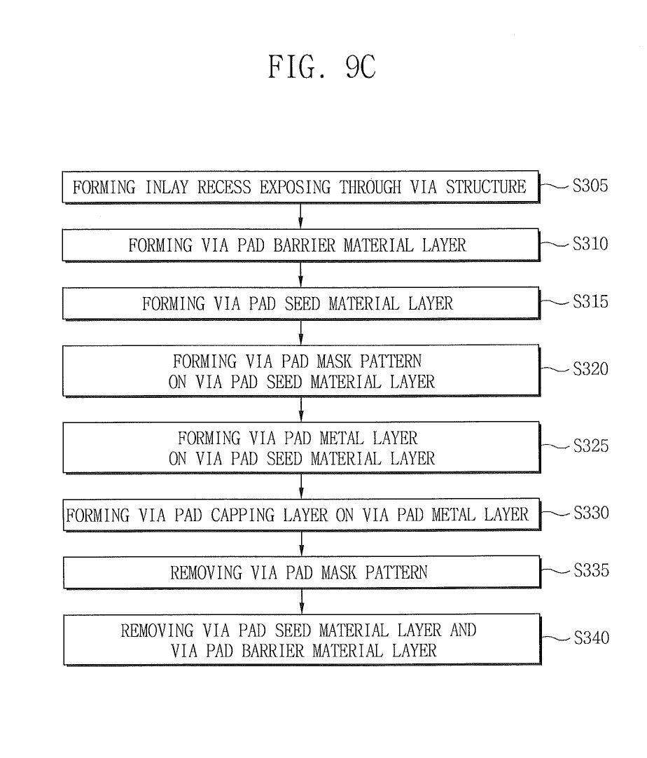

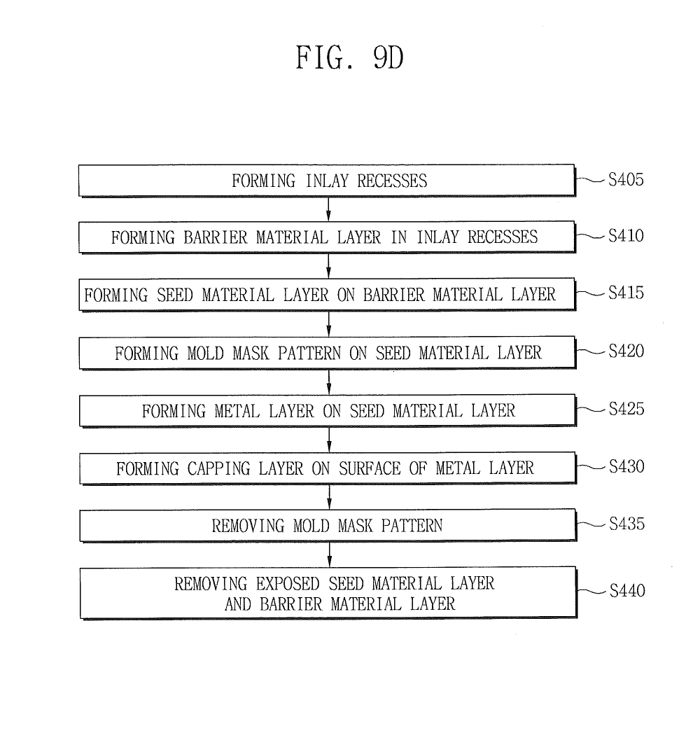

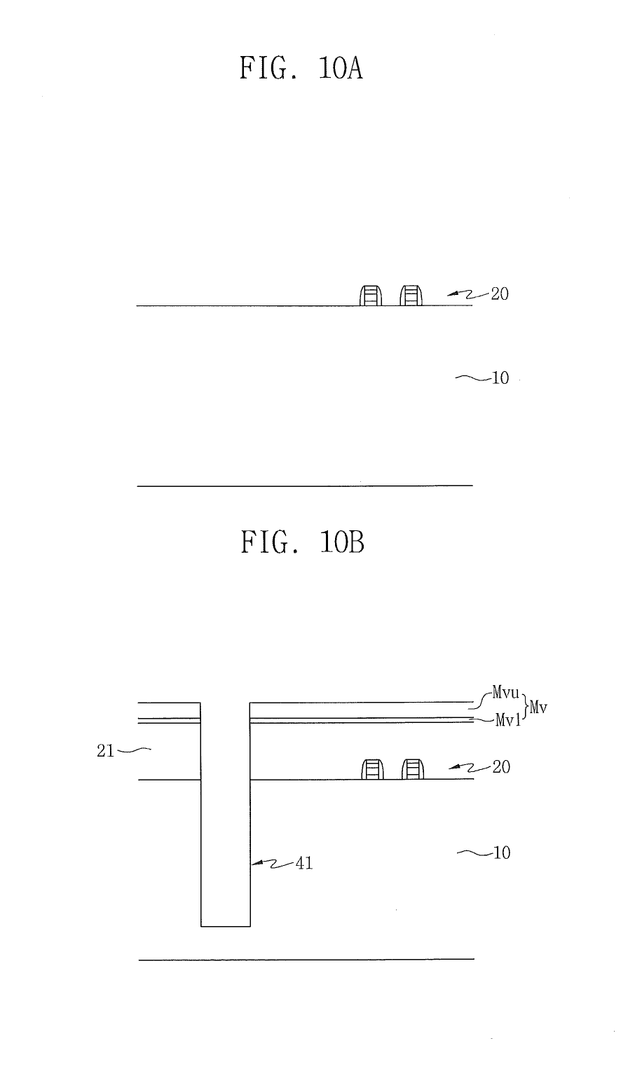

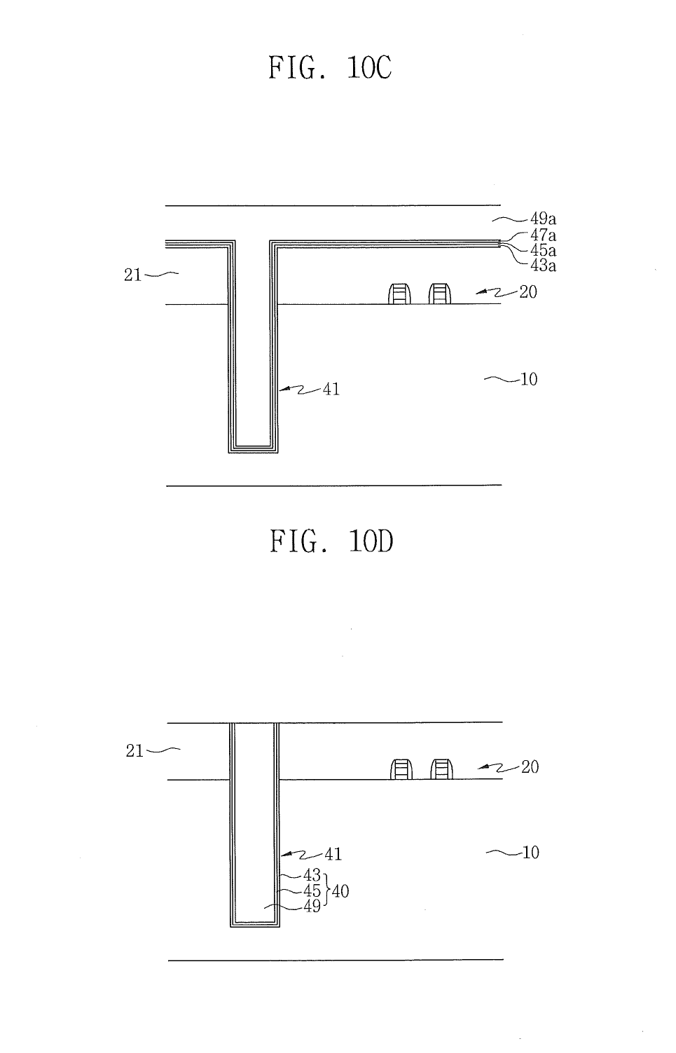

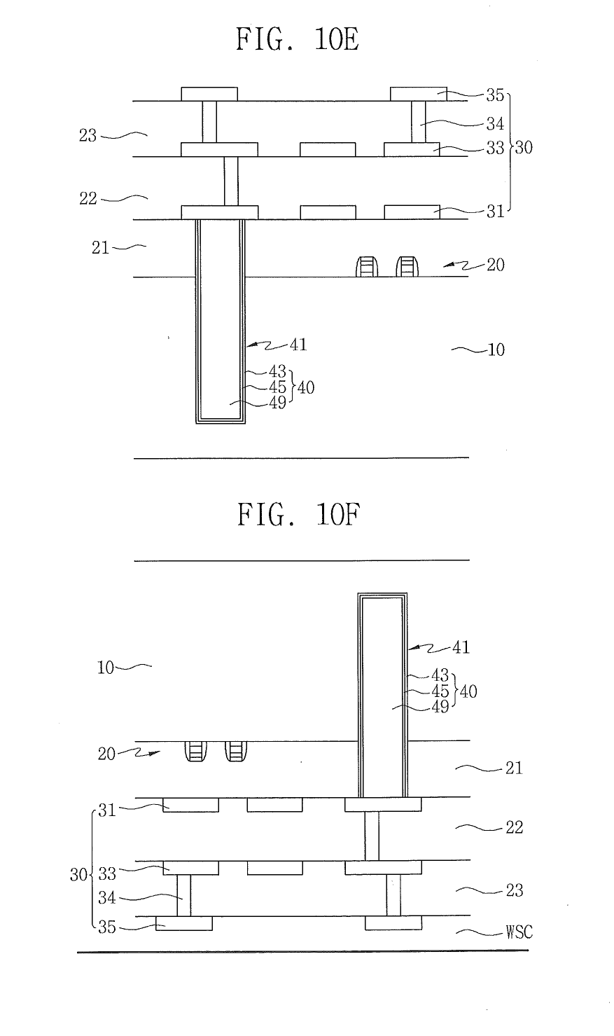

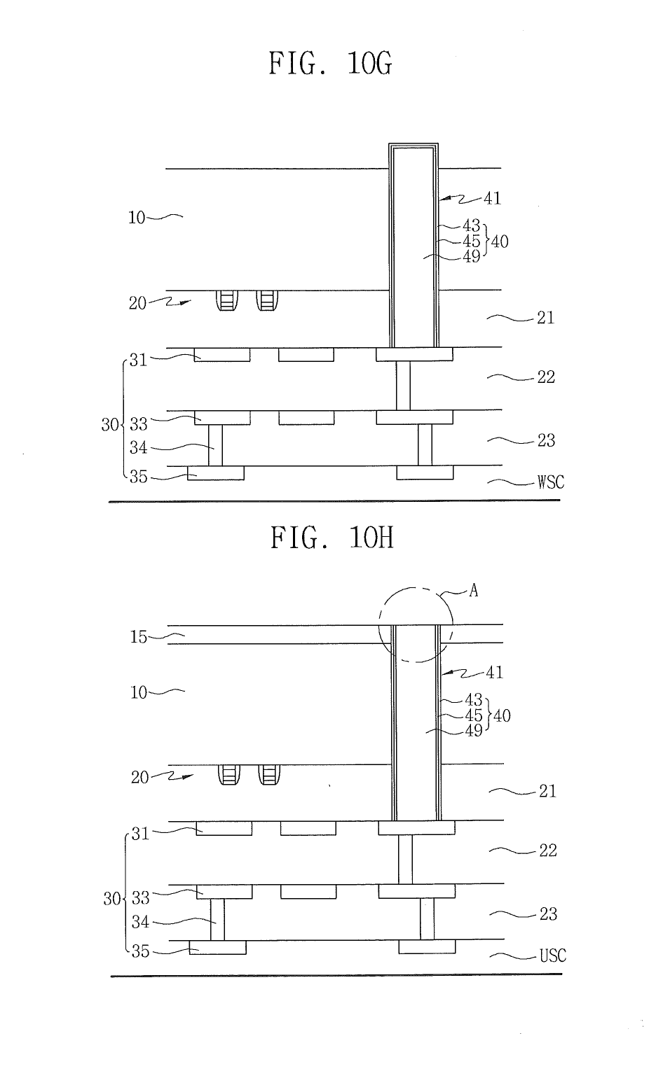

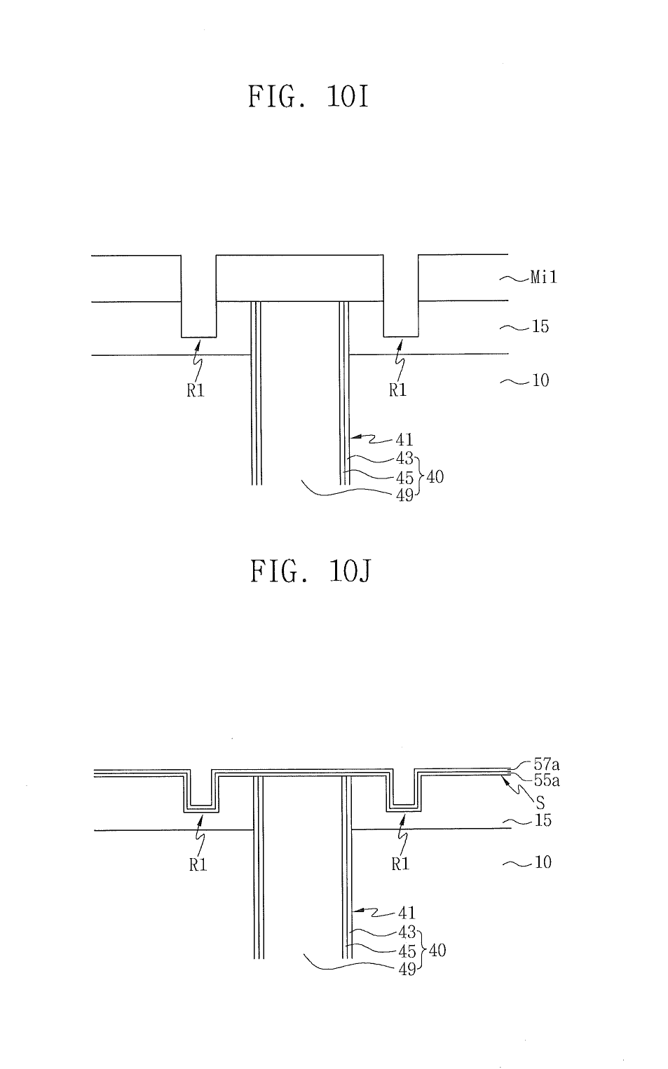

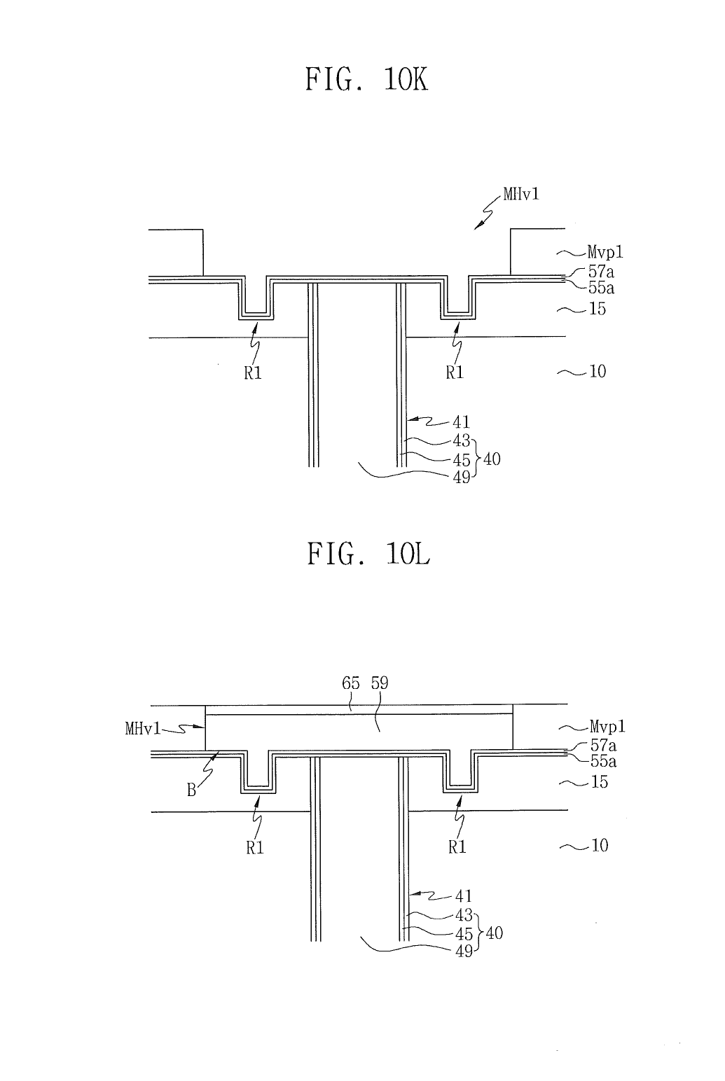

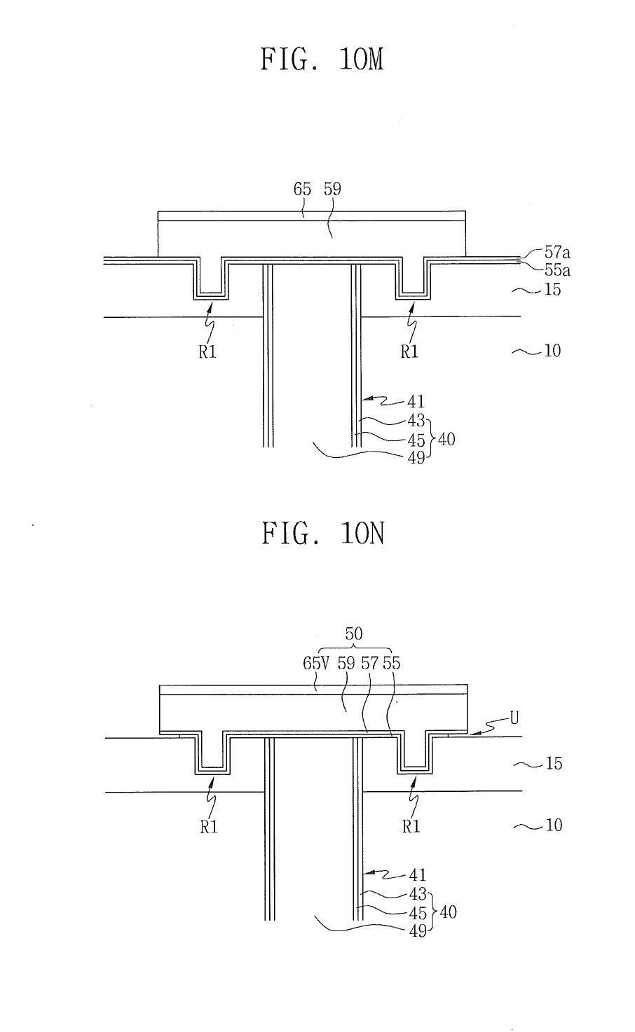

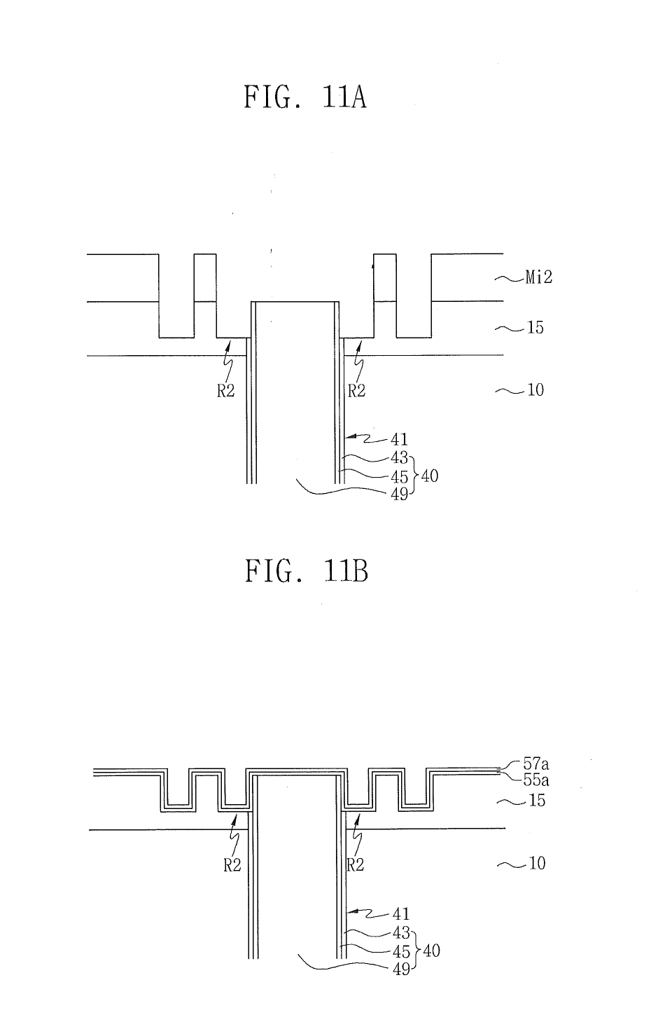

FIGS. 9A to 9D are flowcharts describing fabrication methods of semiconductor devices in accordance with various embodiments of the inventive concepts, and FIGS. 10A to 10O are cross-sectional views schematically describing fabrication methods of a semiconductor device in accordance with embodiments of the inventive concepts.

Referring to FIGS. 9A and 10A, fabrication methods of a semiconductor device in accordance with the embodiments of the inventive concepts may include forming a semiconductor circuit 20 on a substrate 10 having silicon (S105). For example, the semiconductor circuit 20 may include a logic circuit having a transistor such as CMOS.

Referring to FIGS. 9A and 10B, the fabrication methods of the semiconductor device in accordance with the embodiments of the inventive concepts may include forming a first interlayer insulating layer 21 covering the semiconductor circuit 20 on the substrate 10 (S110), forming a via mask pattern My on the first interlayer insulating layer 21 (S115), and forming a via hole 41 in the substrate 10 using the via mask pattern My as an etching mask (S120). The first interlayer insulating layer 21 may include silicon oxide. The via mask pattern My may be formed in a single layer, or may include a lower via mask pattern Mvl and an upper via mask pattern Mvu, as described in FIG. 10B. For example, the lower via mask pattern Mvl may include silicon nitride, and the upper via mask pattern Mvu may include a silicon oxide such as a middle temperature oxide (MTO). Then, the via mask pattern My may be removed. In other embodiments, the via mask pattern My may not be removed but used in a following process. In the following description, it is assumed and described that the via mask pattern My is removed.

Referring to FIGS. 9A and 10C, the fabrication methods of the semiconductor device in accordance with the embodiments of the inventive concepts may include conformally forming a via liner material layer 43a on an inner wall of the via hole 41 (S125), conformally forming a via barrier material layer 45a on the via liner material layer 43a (S130), forming a via seed material layer 47a on the via barrier material layer 45a (S135), and forming a via plug material layer 49a on the via seed material layer 47a to fully fill the via hole 41 (S140).

The via liner material layer 43a may include silicon oxide and/or silicon nitride. For example, the via liner material layer 43a may be conformally formed on the inner wall of the via hole 41 using an atomic layer deposition (ALD) method, a plasma enhanced chemical vapor deposition (PECVD) method and/or a sub-atmospheric chemical vapor deposition (SACVD) method. On the other hand, the via liner material layer 43a may be formed only on the inner wall of the via hole 41 using a thermal oxidation method, etc. In this embodiment, it is assumed and described that the via liner material layer 43a includes a silicon oxide formed by the SACVD method.

The via barrier material layer 45a may be conformally formed of a barrier metal on an inner wall of the via liner material layer 43a, using a physical vapor deposition (PVD) method such as sputtering, and/or a metal organic chemical vapor deposition (MOCVD) method. The via barrier material layer 45a may include Ti, TiN, Ta, TaN, TiW, and/or WN, etc. The via barrier material layer 45a may be formed in a single or multi layer.

The via seed material layer 47a may be conformally formed of Cu, Ru, W, and/or another seed metal on the via barrier material layer 45a, using a PVD or CVD method. The via plug material layer 49a may be formed by a plating method. When the via seed material layer 47a and the via plug material layer 49a include the same material, the via seed material layer 47a and the via plug material layer 49a have no boundary therebetween. For example, when both the via seed material layer 47a and the via plug material layer 49a include copper, the via seed material layer 47a and the via plug material layer 49a have no boundary therebetween. Therefore, the via seed material layer 47a and the reference mark thereof will be omitted in the following drawings.

Referring to FIGS. 9A and 10D, the fabrication methods of the semiconductor device in accordance with the embodiments of the inventive concepts may include forming a through-via structure 40 (S145). The formation of the through-via structure 40 may include removing the via plug material layer 49a, the via seed material layer 47a, the via barrier material layer 45a, and the via liner material layer 43a which are formed on the top surface of the first interlayer insulating layer 21, by a planarization method such as CMP, to form a via plug 49, a via barrier layer 45, and a via liner 43. During the planarization process, top surfaces of the through-via structure 40 and first interlayer insulating layer 21 may be planarized.

Referring to FIGS. 9A and 10E, the fabrication methods of the semiconductor device in accordance with the embodiments of the inventive concepts may include forming conductive patterns 30 on the through-via structure 40 and first interlayer insulating layer 21 (S150). The conductive patterns 30 may include internal interconnections 31, 33, and 35, and internal via plugs 34. The internal interconnections 31, 33, and 35 may include multi layered doped polysilicon, metal silicide, a metal, and/or a metal composite. A second interlayer insulating layer 22 and a third interlayer insulating layer 23 may be formed to surround or cover the conductive patterns 30.

Referring to FIGS. 9A and 10F, the fabrication methods of the semiconductor device in accordance with the embodiments of the inventive concepts may include inverting the substrate 10, followed by placing the substrate 10 on a wafer supporting carrier WSC (S155). The wafer supporting carrier WSC may include an insulating material and a material having cushioning and elasticity to prevent damage of the conductive patterns 30.

Referring to FIGS. 9A and 10G, the fabrication methods of the semiconductor device in accordance with the embodiments of the inventive concepts may include partly removing an upper portion of the substrate 10 to expose an end of the through-via structure 40 (S160) The removal of the upper portion of the substrate 10 in part may include grinding, CMP and/or an etchback process. The end of the through-via structure 40 may protrude higher than the surface of the lowered substrate 10. In this process, the via liner 43 and/or via barrier layer 45 on the end of the through-via structures 40 may be partly removed. In FIG. 10G, the via liner 43 and via barrier layer 45 on the end of the through-via structure 40 are assumed and described as not being removed but remaining, so that the inventive concepts can be understood.

Referring to FIGS. 9A and 10H, the fabrication methods of the semiconductor device in accordance with the embodiments of the inventive concepts may include forming a surface insulating layer 15 on a surface of the substrate 10, and planarizing the surface of the surface insulating layer 15 in order to expose the end of the through-via structure 40 on the surface of the surface insulating layer 15 (S165). In this process, the via plug 49 may be exposed on the end surface of the through-via structure 40. For example, the via liner 43 and via barrier layer 45 on the end of the through-via structure 40 may be partially or fully removed. In another embodiment, the via barrier layer 45 may partially or fully remain on the end surface of the through-via structure 40. In this embodiment, the via plug 49 is assumed and explained as being exposed on the end surface of the through-via structure 40. Starting from FIG. 10I, the region A in FIG. 10H will be enlarged and explained so that the inventive concepts can be understood.

Referring to FIGS. 9B and 10I, the fabrication methods of the semiconductor device in accordance with the embodiments of the inventive concepts may include forming an inlay mask pattern Mi1 on the surface insulating layer 15 (S205) and forming an inlay recess R1 in the surface insulating layer 15 using the inlay mask pattern Mi1 as an etching mask (S210). The formation of the inlay recess R1 may include selectively removing or recessing the surface of the surface insulating layer 15 exposed by the inlay mask pattern Mi1. Then, the inlay mask pattern Mi1 may be removed.

Referring to FIGS. 9B and 10J, the fabrication methods of the semiconductor device in accordance with the embodiments of the inventive concepts may include conformally forming a via pad barrier material layer 55a on the surface of the surface insulating layer 15 and an inner surface of the inlay recess R1 (S215) and forming a via pad seed material layer 57a on the via pad barrier material layer 55a (S220).

Referring to FIGS. 9B and 10K, the fabrication methods of the semiconductor device in accordance with the embodiments of the inventive concepts may include forming a via pad mask pattern Mvp1 on the via pad seed material layer 57a (S225). The via pad mask pattern Mvp1 may have a via pad mold hole MHv1 corresponding to the shapes of the via pads 50 illustrated in other drawings herein. For example, the via pad mask pattern Mvp1 may include a photoresist.

Referring to FIGS. 9B and 10L, the fabrication methods of the semiconductor device in accordance with the embodiments of the inventive concepts may include forming a via pad metal layer 59 on the via pad seed material layer 57a so as to fill the via pad mold hole MHv1 (S230), and forming a via pad capping layer 65 on a surface of the via pad metal layer 59 (S235). The via pad metal layer 59 may be formed using a plating method. The via pad capping layer 65 may be formed using a surface treatment method such as a plating or deposition method. The via pad metal layer 59 may include, for example, Cu. The via pad capping layer 65 may include an anti-oxidation metal such as Ni, Ag, and/or Au. Although upper surfaces of the via pad capping layer 65 and the via pad mask pattern Mvp1 are described as flat in FIG. 10L, this may be different. When the via pad seed material layer 57a and the via pad metal layer 59 have the same material, a boundary B therebetween may disappear. However, the boundary B between the via pad seed material layer 57a and the via pad metal layer 59 is illustrated in the drawings herein, so that the inventive concepts can be understood. In addition, when the via pad seed material layer 57a and the via pad metal layer 59 include a different material, the boundary B may be maintained.

Referring to FIGS. 9B and 10M, the fabrication methods of the semiconductor device in accordance with the embodiments of the inventive concepts may include removing the via pad mask pattern Mvp1 (S240). The removal of the via pad mask pattern Mvp1 may include a process of removing the photoresist, such as sulfuric acid boiling and/or oxygen plasma treatment. By removing the via pad mask pattern Mvp1, the via pad seed material layer 57a disposed below the via pad mask pattern Mvp1 may be exposed.

Referring to FIGS. 9B and 10N, the fabrication methods of the semiconductor device in accordance with the embodiments of the inventive concepts may include selectively removing the exposed via pad seed material layer 57a and the via pad barrier material layer 55a disposed below the via pad seed material layer 57a (S245). The removal of the exposed via pad seed material layer 57a and the via pad barrier material layer 55a disposed below the via pad seed material layer 57a may include, for example, a wet etching method using SC-1 solution including H₂O₂ and/or NH₄OH. Through the process in S245, a via pad 50 including a via pad barrier layer 55, a via pad seed layer 57, a via pad metal layer 59, and a via pad capping layer 65 may be formed. In addition, the via pad barrier material layer 55a may be over-etched during the process in S245. For example, undercuts U may occur below the via pad metal layer 59 or via pad seed layer 57

As described above, even when the undercuts U occur below the via pad metal layer 59 or via pad seed layer 57, the undercuts U may have little to no effect on the function of the via pad 50, in accordance with the embodiments of the inventive concepts. In addition, even when the undercuts U are severe, a bad effect on the via pad 50 due to the undercuts U may be weakened since the via pad barrier layer 55 becomes longer corresponding to the inlay recess R1.

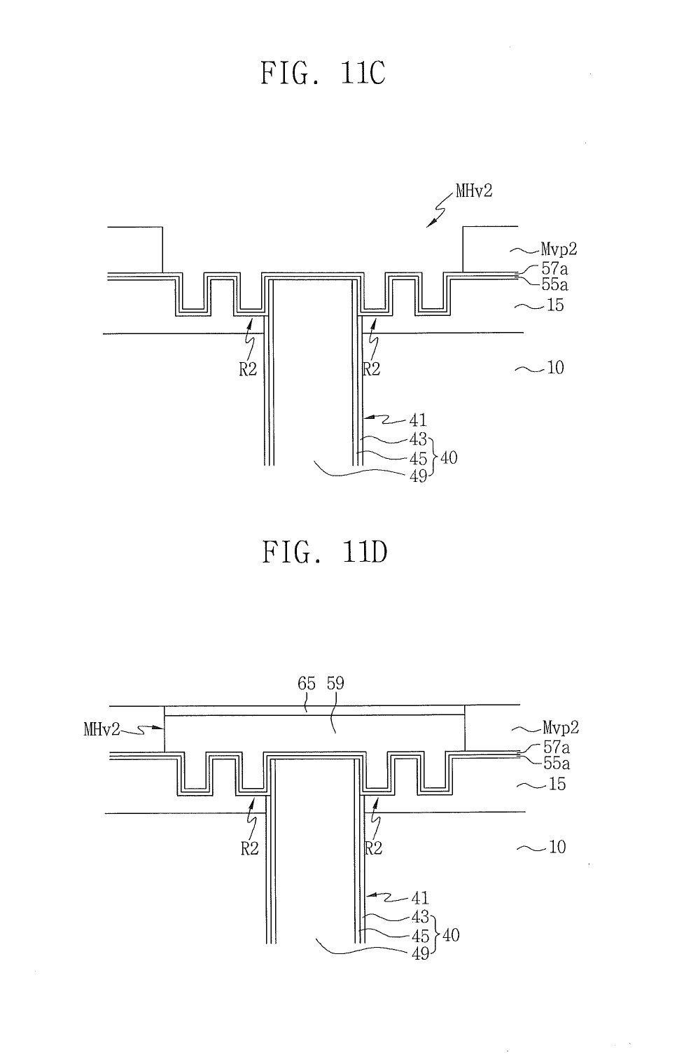

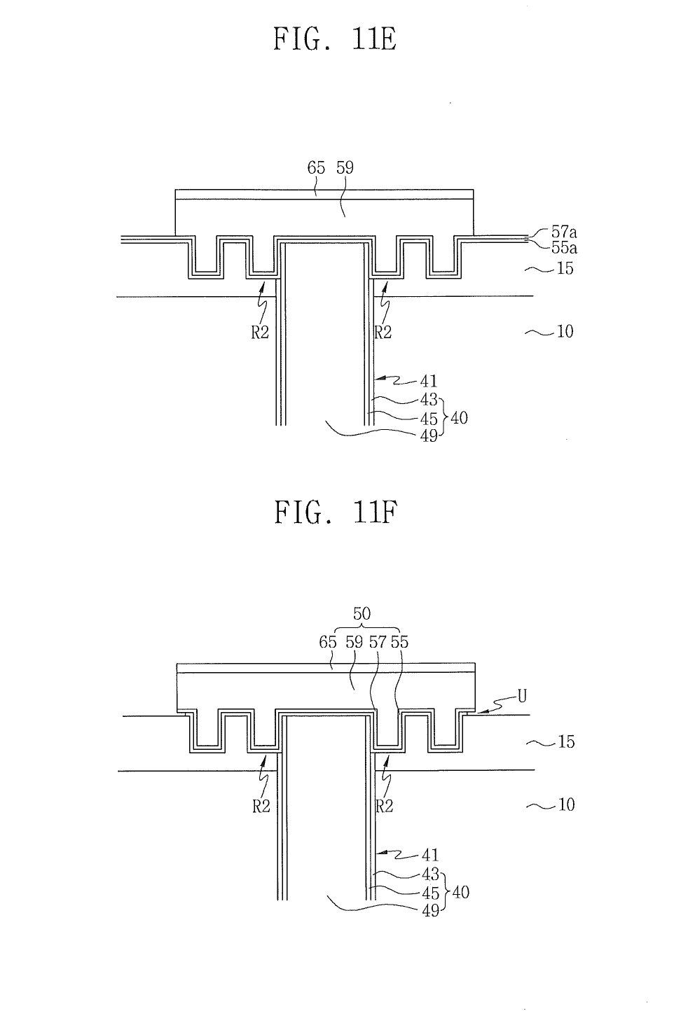

FIGS. 11A to 11F are cross-sectional views schematically describing fabrication methods of a semiconductor device in accordance with embodiments of the inventive concepts.

Referring to FIGS. 9C and 11A, the fabrication methods of the semiconductor device in accordance with the embodiments of the inventive concepts may include, first, performing the processes in steps S105 to S165 referring to FIGS. 9A and 10A to 10H, followed by forming an inlay recess R2 exposing a top and/or side surfaces of the through-via structure 40 (S305). For example, the formation of the inlay recess R2 may include forming an inlay mask pattern Mi2 selectively exposing the end of the through-via structure 40 or via plug 49 and the surface of the surface insulating layer 15, and recessing the surface of the exposed surface insulating layer 15. During the process in step S305, the via liner 43 exposed in the inlay recess R2 may be partially or fully eliminated. In addition, the via barrier layer 45 exposed in the inlay recess R2 may be partially or fully eliminated. In this embodiment, it is assumed and described that the via liner 43 exposed in the inlay recess R2 is fully eliminated and the via barrier layer 45 remains intact, as an example. Next, the inlay mask pattern Mi2 may be removed.

Referring to FIG. 11B, the fabrication methods of the semiconductor device in accordance with the embodiments of the inventive concepts, with further reference to FIG. 10J, may include conformally forming a via pad barrier material layer 55a on a top surface of the surface insulating layer 15, top and side surfaces of the exposed via plug 49, and an inner surface of the inlay recess R2 (S310), and conformally forming a via seed material layer 57a on the via pad barrier material layer 55a (S315).

Referring to FIG. 11C, the fabrication methods of the semiconductor device in accordance with the embodiments of the inventive concepts, with further reference to FIG. 10K, may include forming a via pad mask pattern Mvp2 having a via pad mold hole MHv2 on the via pad seed material layer 57a (S320). The via pad mold hole MHv2 may have one of the shapes of the via pads 50I and 50J illustrated in FIGS. 4A and 4B. In this embodiment, the shape of via pad mold hole MHv2 has that of the via pad 50J illustrated in FIG. 4B.

Referring to FIG. 11D, the fabrication methods of the semiconductor device in accordance with the embodiments of the inventive concepts, with further reference to FIG. 10L, may include forming a via pad metal layer 59 on the via pad seed material layer 57a to fill the via pad mold hole MHv2 (S325) and forming a via pad capping layer 65 on the surface of the via pad metal layer 59 (S330).

Referring to FIG. 11E, the fabrication methods of the semiconductor device in accordance with the embodiments of the inventive concepts, with further reference to FIG. 10M, may include removing the via pad mask pattern Mvp2 (S335).

Referring to FIG. 11F, the fabrication methods of the semiconductor device in accordance with the embodiments of the inventive concepts may include removing the exposed via pad seed material layer 57a and the via pad barrier layer 55a disposed below the via pad seed material layer 55a (S340). By the process in step S340, a via pad 50 having a via pad barrier layer 55, a via pad seed layer 57, a via pad metal layer 59, and a via pad capping layer 65 may be formed. In addition, during the process in step S340, the via pad barrier layer 55 may be over-etched to form undercuts U below the via pad metal layer 59 or via pad seed layer 57.

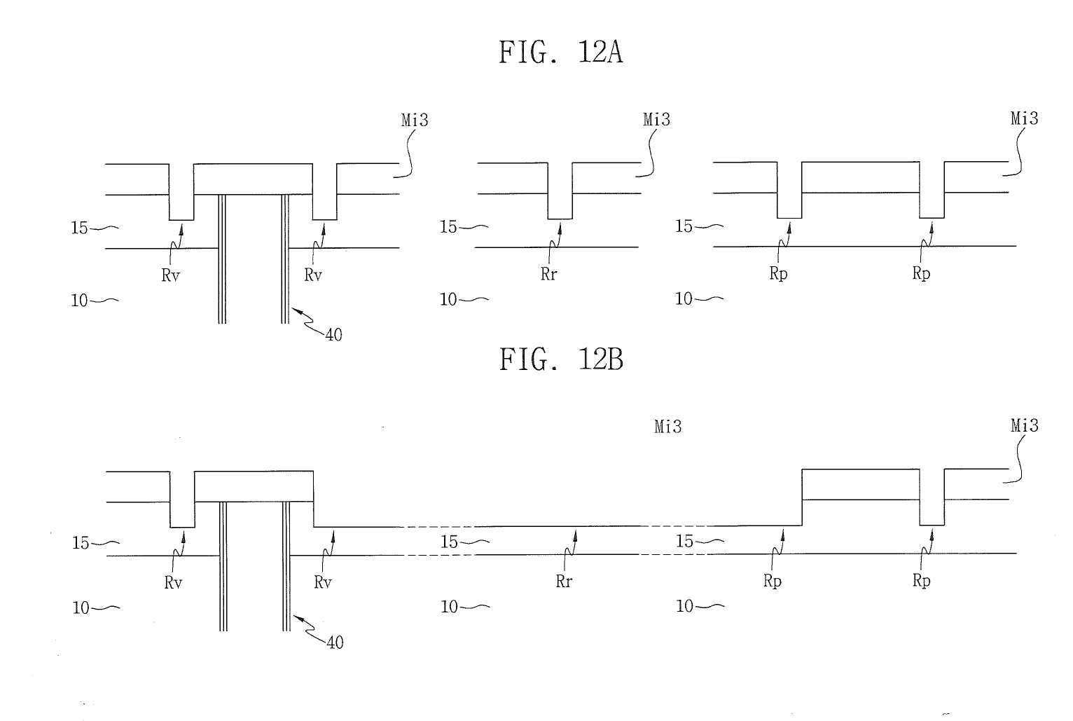

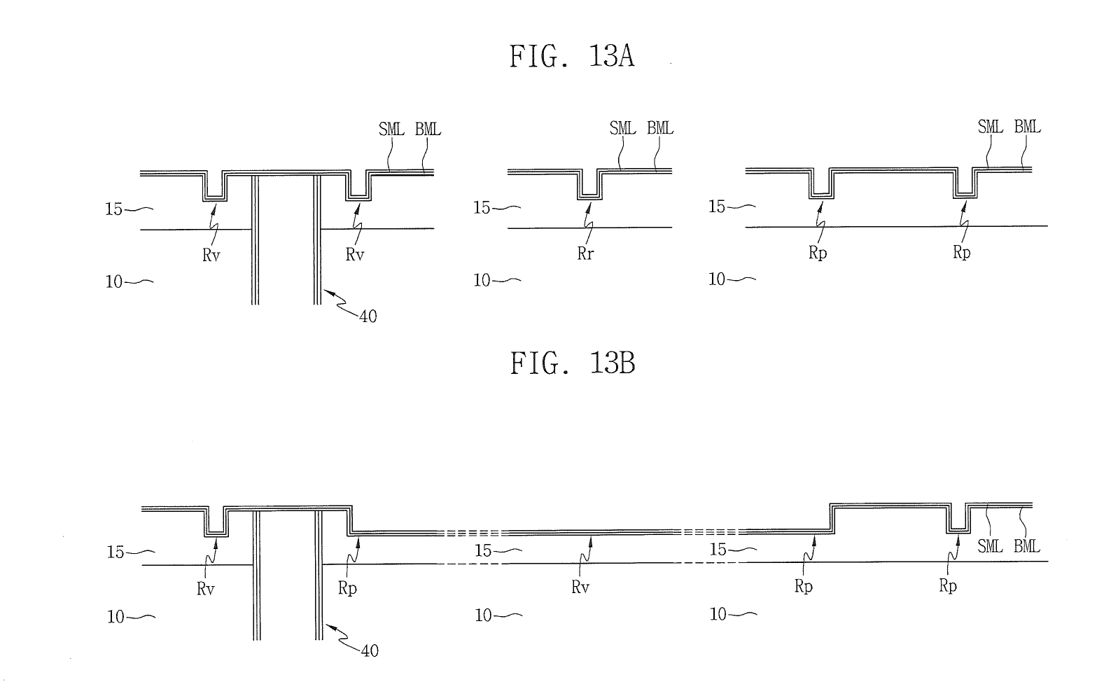

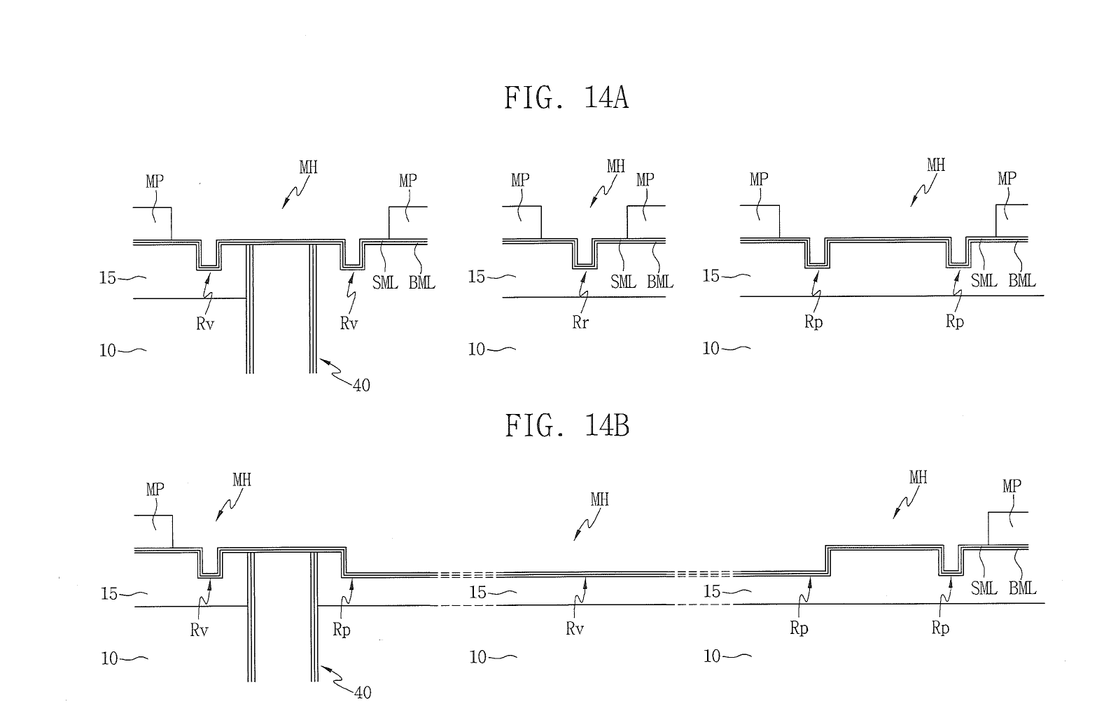

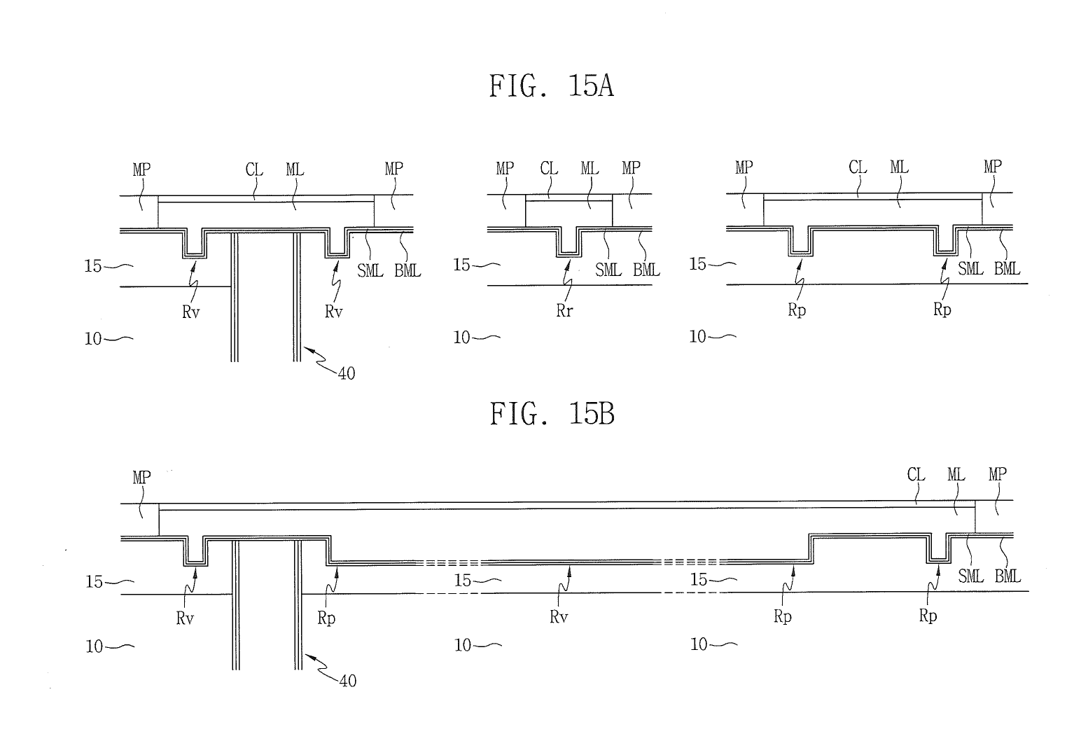

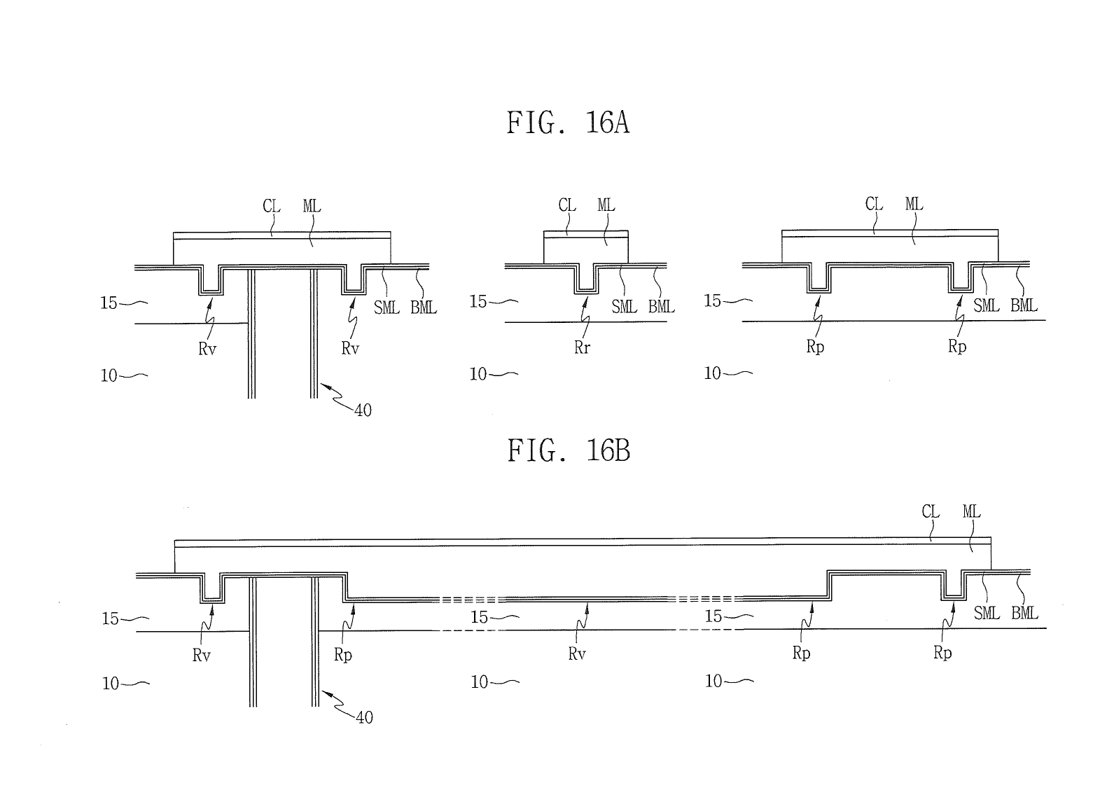

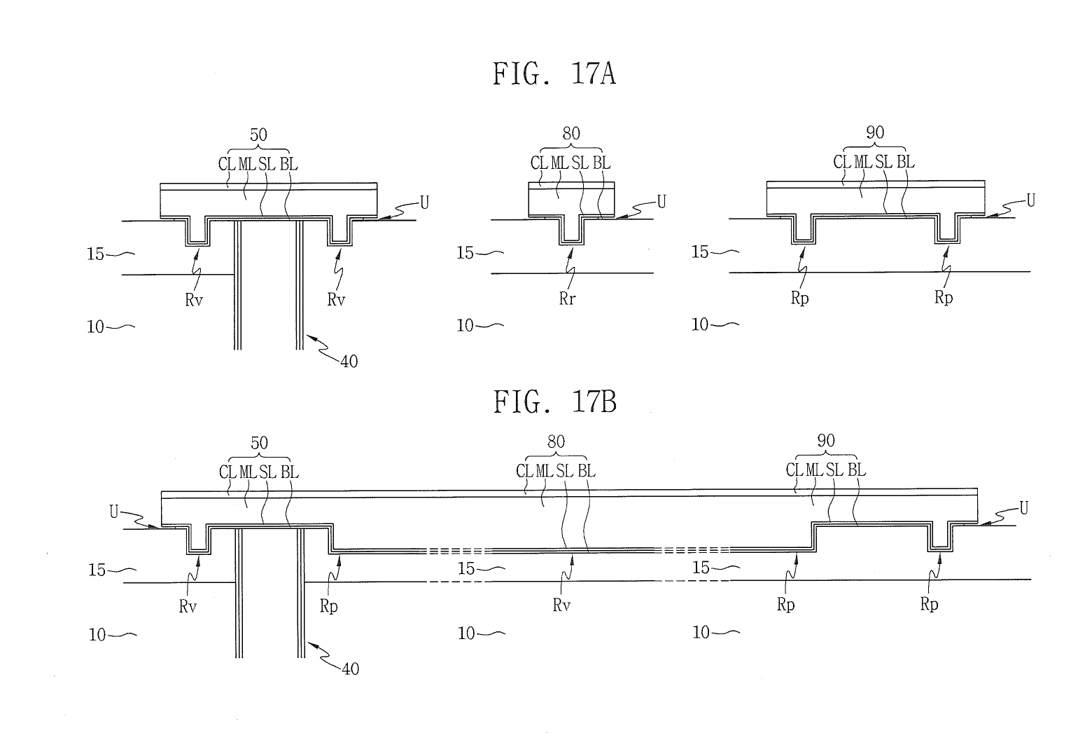

FIGS. 12A and 12B to FIGS. 17A and 17B are cross-sectional views schematically illustrating a fabrication method of a semiconductor device in accordance with embodiments of the inventive concepts.

Referring to FIG. 9D and FIGS. 12A and 12B, fabrication methods of a semiconductor device in accordance with embodiments of the inventive concepts may include, first, performing the process in steps S105 to S165 referring to FIG. 9A and FIGS. 10A to 10I, followed by forming inlay recesses Rv, Rr, and Rp (S405). For example, the formation of the inlay recesses Rv, Rr, and Rp may include forming an inlay mask pattern Mi3 selectively exposing the surfaces of the through-via structure 40 and surface insulating layer 15, and recessing the surface of the surface insulating layer 15. The inlay recesses Rv, Rr, and Rp may selectively include a via pad inlay recess Rv, an interconnection inlay recess Rr, and/or a redistribution pad inlay recess Rp.

Referring to FIG. 9D and FIGS. 13A and 13B, the fabrication methods of the semiconductor device in accordance with the embodiments of the inventive concepts may include conformally forming a barrier material layer BML on the surface of the surface insulating layer 15 and inner surfaces of the inlay recesses Rv, Rr, and Rp (S410), and conformally forming a seed material layer SML on the barrier material layer BML (S415).

Referring to FIG. 9D and FIGS. 14A and 14B, the fabrication methods of the semiconductor device in accordance with the embodiments of the inventive concepts may include forming a mold mask pattern MP on the seed material layer SML (S420). The mold mask pattern MP may have mold holes MH corresponding to the shapes of the via pads 50, the redistribution structures 80, and the redistribution pads 90 illustrated in FIGS. 7A to 8C.

Referring to FIG. 9D and FIGS. 15A and 15B, the fabrication methods of the semiconductor device in accordance with the embodiments of the inventive concepts may include forming a metal layer ML on the seed material layer SML to fill the mold hole MH (S425), and forming a capping layer CL on the surface of the metal layer ML (S430). In FIGS. 15A and 15B, although surfaces of the capping layer CL and the mask pattern MP are described as flat, this may be different.

Referring to FIG. 9D and FIGS. 16A and 16B, the fabrication methods of the semiconductor device in accordance with the embodiments of the inventive concepts may include removing the mold mask pattern MP (S435). By the removal of the mold mask pattern MP, the seed material layer SML and barrier material layer BML disposed below the mold mask pattern MP may be exposed.

Referring to FIG. 9D and FIGS. 17A and 17B, the fabrication methods of the semiconductor device in accordance with the embodiments of the inventive concepts may include removing the exposed seed material layer SML and the barrier material layer BML (S440). By the process in step S440, a via pad 50, a redistribution structure 80, and a redistribution pad 90 which include a barrier layer BL, a seed layer SL, the metal layer ML, and the capping layer CL may be formed. In addition, the barrier material layer BML may be over-etched during the process in step S440. For example, undercuts U may occur under the metal layer ML or seed layer SL.

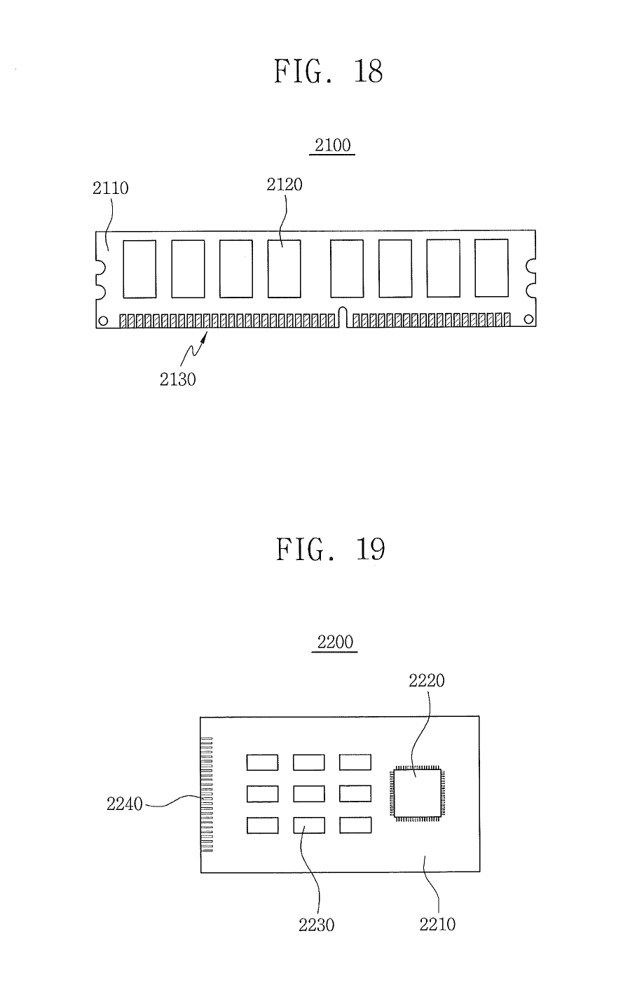

FIG. 18 is a schematic view illustrating a memory module 2100 including at least one of the semiconductor devices 1A and 1B, 11A to 11E, and 12A to 12C in accordance with the various embodiments of the inventive concepts. Referring to FIG. 18, the memory module 2100 may include a memory module substrate 2110, a plurality of memory devices 2120 and terminals 2130 disposed on the memory module substrate 2110. The memory module substrate 2110 may include a printed circuit board (PCB) or a wafer. The memory devices 2120 may be one or more of the semiconductor devices 1A and 1B, 11A to 11E, and 12A to 12C in accordance with the various embodiments of the inventive concepts, or a semiconductor package having one or more of the semiconductor devices 1A and 1B, 11A to 11E, and 12A to 12C. The plurality of terminals 2130 may include a conductive metal. Each terminal may be electrically connected to each of the semiconductor devices 2120. Because the memory module 2100 includes a semiconductor device having low leakage current and excellent on/off current characteristics, the memory module 2100 may exhibit improved module performance.

FIG. 19 is a schematic view illustrating a semiconductor module 2200 including at least one of the semiconductor devices 1A and 1B, 11A to 11E, and 12A to 12C in accordance with the various embodiments of the inventive concepts. Referring to FIG. 19, the semiconductor module 2200 in accordance with the various embodiments of the inventive concepts may include one or more of the semiconductor devices 1A and 1B, 11A to 11E, and 12A to 12C in accordance with various embodiments of the inventive concepts, mounted on a semiconductor module substrate 2210. The semiconductor module 2200 may further include a microprocessor 2220 mounted on the module substrate 2210. Input/output terminals 2240 may be disposed on at least one side of the module substrate 2210.

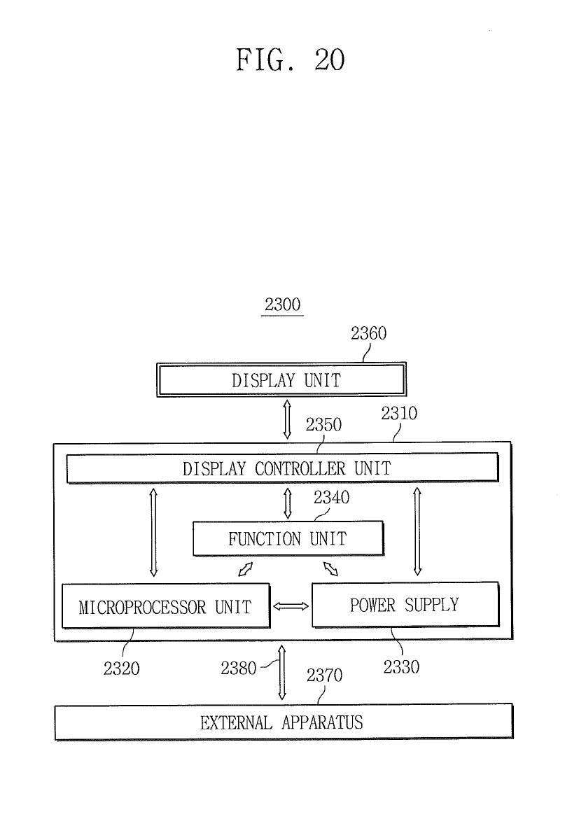

FIG. 20 is a block diagram schematically illustrating an electronic system 2300 including at least one of the semiconductor devices 1A and 1B, 11A to 11E, and 12A to 12C in accordance with the various embodiments of the inventive concepts. Referring to FIG. 20, one or more of the semiconductor devices 1A and 1B, 11A to 11E, and 12A to 12C in accordance with the various embodiments of the inventive concepts may be applied to the electronic system 2300. The electronic system 2300 may include a body 2310. The body 2310 may include a microprocessor unit 2320, a power supply 2330, a function unit 2340, and/or a display controller unit 2350. The body 2310 may be a system board or motherboard having a PCB. The microprocessor unit 2320, the power supply 2330, the function unit 2340, and the display controller unit 2350 may be installed or mounted on the body 2310. A display unit 2360 may be disposed outside or on a surface of the body 2310. For example, the display unit 2360 may be disposed on the surface of the body 2310 to display an image processed by the display controller unit 2350. The power supply 2330 may receive a constant voltage from an external power source, etc., divide the voltage into various levels of voltages, and supply those voltages to the microprocessor unit 2320, the function unit 2340, and the display controller unit 2350, etc. The microprocessor unit 2320 may receive the voltage from the power supply unit 2330 to control the function unit 2340 and the display unit 2360. The function unit 2340 may perform functions of various electronic systems 2300. For example, if the electronic system 2300 is a mobile electronic product such as cellular phone, the function unit 2340 may include several components which can perform functions of wireless communication such as imaging output to the display unit 2360 and sound output to a speaker by dialing or communicating with an external apparatus 2370, and if a camera is installed, the function unit 2340 may function as an image processor. In another example embodiment, when the electronic system 2300 is connected to a memory card, etc. in order to expand capacity, the function unit 2340 may be a memory card controller. The function unit 2340 may exchange signals with the external apparatus 2370 through a wired or wireless communication unit 2380. Further, when the electronic system 2300 needs a universal serial bus (USB) in order to expand functionality, the function unit 2340 may function as an interface controller. One or more of the semiconductor devices 1A and 1B, 11A to 11E, and 12A to 12C in accordance with the various embodiments of the inventive concepts may be included in at least one of the microprocessor unit 2320 and the function unit 2340.

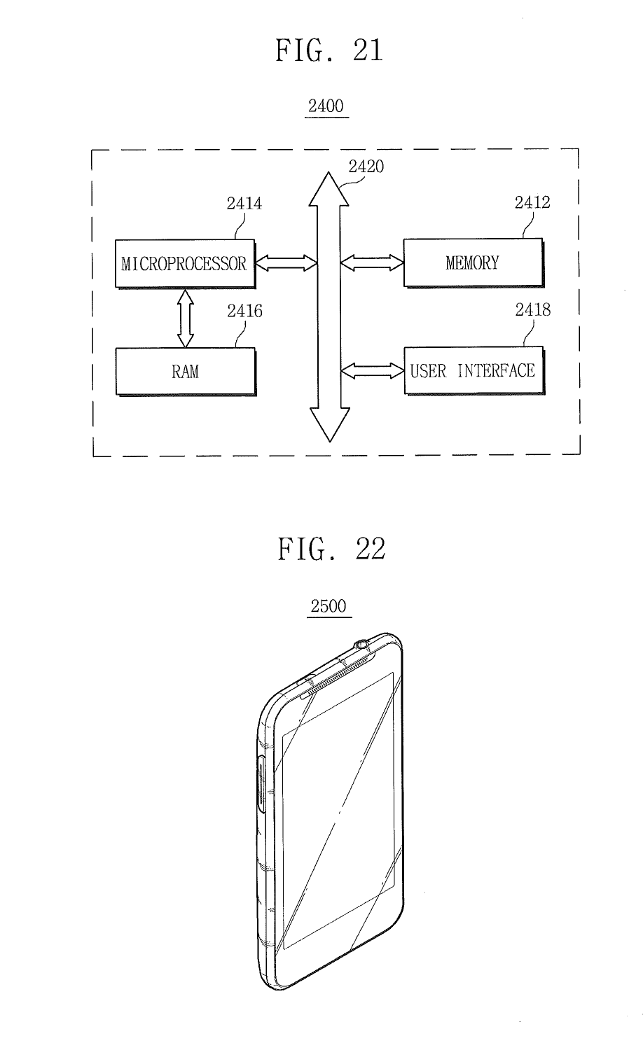

FIG. 21 is a schematic block diagram illustrating another electronic system 2400 including one or more of the semiconductor devices 1A and 1B, 11A to 11E, and 12A to 12C in accordance with the embodiments of the inventive concepts. Referring to FIG. 21, the electronic system 2400 may include at least one of the semiconductor devices 1A and 1B, 11A to 11E, and 12A to 12C in accordance with the various embodiments of the inventive concepts. The electronic system 2400 may be used to provide a mobile apparatus or a computer. For example, the electronic system 2400 may include a memory system 2412, a microprocessor 2414, a random access memory (RAM) 2416, and a user interface 2418 performing data communication using a bus 2420. The microprocessor 2414 may program and control the electronic system 2400. The RAM 2416 may be used as an operation memory of the microprocessor 2414. For example, the microprocessor 2414 or the RAM may include at least one of the semiconductor devices 1A and 1B, 11A to 11E, and 12A to 12C in accordance with the various embodiments of the inventive concepts. The microprocessor 2414, the RAM 2416, and/or other components can be assembled in a single package. The user interface 2418 may be used to input data to or output data from the electronic system 2400. The memory system 2412 may store codes for operating the microprocessor 2414, data processed by the microprocessor 2414, or external input data. The memory system 2412 may include a controller and a memory.

FIG. 22 is a schematic diagram illustrating a mobile apparatus 2500 including at least one of the semiconductor devices 1A and 1B, 11A to 11E, and 12A to 12C in accordance with the various embodiments of the inventive concepts. The mobile apparatus 2500 may include a mobile phone or a tablet PC. Further, at least one of the semiconductor devices 1A and 1B, 11A to 11E, and 12A to 12C in accordance with the various embodiments of the inventive concepts may be used in a portable computer such as a notebook, a Moving Picture Experts Group (MPEG)-1 audio layer 3 (MP3) player, an MP4 player, a navigation apparatus, a solid state disk (SSD), a table computer, an automobile, or a home appliance, as well as the mobile phone or the tablet PC.

Semiconductor devices in accordance with various embodiments of the inventive concepts may include via pads which are mechanically and physically stable. The semiconductor devices in accordance with various embodiments of the inventive concepts may include redistribution structures and redistribution pads which are mechanically and physically stable. The semiconductor devices in accordance with various embodiments of the inventive concepts may reduce or minimize the effect of undercuts caused by wet etching, etc. The semiconductor devices in accordance with various embodiments of the inventive concepts may have low contact resistance between the through-via structure and the via pad, since a contact between the through-via structure and the via pad remains stable. Accordingly, superior electrical performance of the semiconductor devices may be provided.

The foregoing is illustrative of embodiments and is not to be construed as limiting thereof. Although a few embodiments have been described, those skilled in the art will readily appreciate that many modifications are possible in embodiments without materially departing from the novel teachings and advantages. Accordingly, all such modifications are intended to be included within the scope of the inventive concepts as defined in the claims. In the claims, means-plus-function clauses are intended to cover the structures described herein as performing the recited function, and not only structural equivalents but also equivalent structures. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A semiconductor device, comprising:
a through-via structure vertically passing through a substrate, an end surface of the through-via structure being exposed on a surface of the substrate; and
a via pad on the through-via structure, wherein the via pad comprises:
a via pad body; and
a via pad inlay below the via pad body and located at a lateral sides of the through-via structure.

2. The semiconductor device of claim 1, further comprising:
a surface insulating layer located between the substrate and the via pad, wherein the via pad is directly in contact with the surface insulating layer.

3. The semiconductor device of claim 2, wherein the surface insulating layer includes a recess configured to surround the via pad inlay.

4. The semiconductor device of claim 3, wherein the via pad inlay includes a sidewall and a bottom, and the sidewall is directly in contact with the through-via structure.

5. The semiconductor device of claim 4, wherein the via pad body comprises:
a via pad barrier layer on the surface insulating layer; and
a via pad metal layer on the via pad barrier layer, the via pad barrier layer being directly in contact with the through-via structure.

6. The semiconductor device of claim 5, wherein the via pad barrier layer extends onto a surface of the recess, and the via pad metal layer extends on the via pad barrier layer on the surface of the recess to fill the recess.

7. The semiconductor device of claim 2, further comprising:
a buffer insulating layer located between the substrate and the surface insulating layer.

8. The semiconductor device of claim 7, wherein the surface insulating layer includes silicon nitride, and the buffer insulating layer includes silicon oxide.

9. The semiconductor device of claim 1, further comprising:
a passivation layer that surrounds a sidewall of the via pad.

10. The semiconductor device of claim 1, wherein the via pad body has a mesa shape with a flat top surface, and the via pad further comprises a via pad capping layer on the via pad body and having a flat top surface.

11. The semiconductor device of claim 1, wherein the through-via structure comprises:
a via hole in the substrate;
a via barrier layer that extends conformally on an inner wall of the via hole; and
a via plug on the via barrier layer to fill the via hole, the via plug being directly in contact with the via pad.

12. The semiconductor device of claim 1, further comprising:
a redistribution structure on the substrate, wherein the redistribution structure includes an interconnection body materially continuous with the via pad body.

13. The semiconductor device of claim 12, wherein the redistribution structure further comprises an interconnection inlay located below the interconnection body.

14. The semiconductor device of claim 12, further comprising:
a redistribution pad on the substrate, wherein the redistribution pad comprises a redistribution body materially continuous with the interconnection body and a redistribution inlay located below the redistribution body.

15. A semiconductor device, comprising:
a substrate;
an insulating layer on a surface of the substrate;
a through-via structure vertically passing through the substrate and the insulating layer, a surface of the through-via structure being exposed on the insulating layer; and
a via pad on a surface of the exposed through-via structure, wherein the via pad comprises:
a via pad body directly on the surface of the exposed through-via structure; and
a via pad inlay below the via pad body and protruding into the insulating layer and surrounding the through-via structure,
wherein the via pad body and the via pad inlay comprise a via pad barrier layer directly on the insulating layer, and a via pad metal layer on the via pad barrier layer.

16. A semiconductor device, comprising:
a substrate having first and second opposing substrate faces;
a through-via structure that extends through the substrate, from the first substrate face to the second substrate face, and includes a through-via structure sidewall; and
a via pad on the first substrate face and electrically connected to the through-via structure, the via pad including a first via pad face adjacent the first substrate face, a second via pad face remote from the first substrate face and a via pad sidewall between the first via pad face and the second via pad face, the first via pad face being non-planar between the via pad sidewall and the through-via sidewall.

17. The semiconductor device of claim 16 wherein the first via pad face includes at least one via pad inlay between the via pad sidewall and the through-via sidewall.

18. The semiconductor device of claim 17 wherein a sidewall of the at least one via pad inlay directly contacts the through-via structure sidewall.

19. The semiconductor device of claim 16 further comprising a non-planar barrier layer between the non-planar first via pad face and the first substrate face.

20. The semiconductor device of claim 16 wherein the second via pad face is planar between the via pad sidewall and the through-via sidewall.
